(19) United States
(12) Patent Application Publication
(10) Pub. No.: US 2026/0150550 A1
(43) Pub. Date: May 28, 2026

(54) DISPLAY DEVICE, ELECTRONIC DEVICE, AND METHOD FOR FABRICATING DISPLAY DEVICE

(71) Applicant: Samsung Display Co., Ltd., Yongin-si (KR)

(72) Inventor: Chun Gi YOU, Yongin-si (KR)

(21) Appl. No.: 19/279,657

(22) Filed: Jul. 24, 2025

(30) Foreign Application Priority Data
Nov. 25, 2024 (KR) 10-2024-0169409

(51) Int. Cl. H10K 59/80; H10K 59/12; H10K 59/122; H10K 59/131

(52) U.S. Cl. CPC H10K 59/80518; H10K 59/1201; H10K 59/122; H10K 59/131

(57) ABSTRACT

A display device, for example, a display device in which damage to reflective electrode is prevented or reduced during a cleaning process, an electronic device including the display device, and a method for fabricating the display device are disclosed. The display device may include: a substrate; a first electrode on the substrate; a pixel defining film on the first electrode; a light emitting stack on the first electrode and the pixel defining film; a second electrode on the light emitting stack; a reflective electrode between the substrate and the first electrode; an insulating layer between the reflective electrode and the first electrode; a first via hole penetrating the insulating layer between the reflective electrode and the first electrode; a first via inside the first via hole; and a first barrier layer between the first via hole and the first via, wherein the first barrier layer is composed of titanium nitride.

### CROSS-REFERENCE TO RELATED APPLICATION

The present application claims priority to and the benefit of Korean Patent Application No. 10-2024-0169409, filed on Nov. 25, 2024, in the Korean Intellectual Property Office, the entire content of which is incorporated herein by reference.

### BACKGROUND

### 1. Field

One or more embodiments of the present disclosure relate to a display device, for example, to a display device in which damage to reflective electrode may be prevented (or a degree or occurrence of damage to reflective electrode may be reduced) during a cleaning process, an electronic device including the display device, and a method for fabricating the display device.

### 2. Description of the Related Art

Head mounted displays (HMDs) are an image display device that is worn on a user's head in the form of glasses and/or helmets to form a focus at a close distance in front of the user's eyes. The head mounted displays may implement virtual reality (VR) or augmented reality (AR).

Head mounted displays magnify an image displayed on a small display device by utilizing a plurality of lenses and display the magnified image. Therefore, the display devices applied to the head mounted displays need to provide high-resolution images, for example, images with a resolution of 3000 Pixels Per Inch (PPI) or higher. To this end, an organic light emitting diode on silicon (OLEDoS), which is a high-resolution small organic light emitting display device, is utilized as the display device applied to the head mounted displays. The OLEDoS is an image display device in which an organic light emitting diode (OLED) is on a semiconductor wafer substrate on which a complementary metal oxide semiconductor (CMOS) is arranged.

### SUMMARY

One or more aspects of embodiments of the present disclosure are directed toward a display device in which damage to (of) reflective electrode may be prevented (or a degree or occurrence of damage to reflective electrode may be reduced) during a cleaning process, an electronic device including the display device, and a method for fabricating the display device.

Additional aspects of embodiments will be set forth in part in the description which follows and, in part, will be apparent from the description or may be learned by practice of the presented embodiments of the disclosure.

According to one or more embodiments of the present disclosure, a display device includes: a substrate; a first electrode on the substrate; a pixel defining film on the first electrode; a light emitting stack on the first electrode and the pixel defining film; a second electrode on the light emitting stack; a reflective electrode between the substrate and the first electrode; an insulating (e.g., electrically insulating) layer between the reflective electrode and the first electrode; a first via hole penetrating the insulating layer between the reflective electrode and the first electrode; a first via inside the first via hole; and a first barrier layer between the first via hole and the first via, wherein the first barrier layer is formed or composed of titanium nitride.

According to one or more embodiments of the present disclosure, an electronic device includes: a display device providing a display screen, wherein the display device includes: a substrate; a first electrode on the substrate; a pixel defining film on the first electrode; a light emitting stack on the first electrode and the pixel defining film; a second electrode on the light emitting stack; a reflective electrode between the substrate and the first electrode; an insulating (e.g., electrically insulating) layer between the reflective electrode and the first electrode; a first via hole penetrating the insulating layer between the reflective electrode and the first electrode; a first via inside the first via hole; and a first barrier layer between the first via hole and the first via, wherein the first barrier layer is formed or composed of titanium nitride.

Further, according to one or more embodiments of the present disclosure, a method for fabricating a display device includes: forming or arranging a reflective electrode on a substrate; forming or arranging an insulating (e.g., electrically insulating) layer on the reflective electrode; forming or arranging a via hole exposing the reflective electrode by penetrating the insulating layer; forming or arranging a barrier layer formed or composed of titanium nitride on an insulating (e.g., electrically insulating) layer including the via hole; forming or arranging a via on the barrier layer; removing the via and the barrier layer on the insulating layer; forming or arranging a first electrode on the via; forming or arranging a pixel defining film on the first electrode; forming or arranging a light emitting stack on the first electrode and the pixel defining film; and forming or arranging a second electrode on the light emitting stack and the pixel defining film.

According to one or more embodiments, damage to (of) a reflective electrode may be prevented (or a degree or occurrence of damage to a reflective electrode may be reduced) during cleaning process. For example, titanium fluoride, which forms a permeation path for the cleaning solution, may not be generated because a barrier layer inside a via hole is formed or composed of a titanium nitride, and accordingly, damage to the reflective electrode by the cleaning solution utilized during the cleaning process may be prevented (or a degree of occurrence of damage to the reflective electrode by the cleaning solution utilized during the cleaning process may be prevented). For example, the utilization of titanium nitride as a barrier layer enhances the durability and performance of the reflective electrode, ensuring that the display device maintains high-resolution imaging capabilities even after multiple cleaning cycles. This improvement or enhancement may be for applications in head-mounted displays where consistent image quality is important.

However, aspects and features of embodiments of the present disclosure are not restricted to the one set forth herein. The above and other aspects and features of certain embodiments of the present disclosure will become more apparent to one of ordinary skill in the art to which the present disclosure pertains by referencing the detailed description of the present disclosure given.

### BRIEF DESCRIPTION OF THE DRAWINGS

The above and other aspects and features of certain embodiments of the present disclosure will become more apparent and more readily appreciated from the following description of one or more embodiments, taken in conjunction with the accompanying drawings in which:

FIG. 1 is an exploded perspective view illustrating a display device according to one or more embodiments;

FIG. 2 is a block diagram illustrating a display device according to one or more embodiments;

FIG. 3 is an equivalent circuit diagram of a first sub-pixel according to one or more embodiments;

FIG. 4 is a layout diagram illustrating an example of a display panel according to one or more embodiments;

FIGS. 5 and 6 are layout diagrams illustrating examples of the display area of FIG. 4;

FIG. 7 is a cross-sectional view illustrating an example of a display panel taken along the line I1-I1′ of FIG. 5;

FIG. 8 is a cross-sectional view illustrating area A1 of FIG. 7 in more detail;

FIG. 9 is a cross-sectional view illustrating an example of area A2 of FIG. 8 in more detail;

FIG. 10 is a cross-sectional view illustrating an example of a display panel cut along the line E-E′ of FIG. 4;

FIG. 11 is a cross-sectional view illustrating an example of area A3 of FIG. 10 in more detail;

FIGS. 12-17 are process cross-sectional views illustrating a method for fabricating a display device according to one or more embodiments;

FIG. 18 is a block diagram of an electronic device according to one or more embodiments; and

FIGS. 19-21 are schematic diagrams illustrating electronic devices according to one or more embodiments.

### DETAILED DESCRIPTION

The subject matter of the present invention will be described more fully hereinafter with reference to the accompanying drawings, in which embodiments of present disclosure are shown. This subject matter of the present disclosure may, however, be embodied in different forms and should not be construed as being limited to one or more embodiments set forth herein. Rather, these embodiments are provided as examples so that this disclosure will be thorough and complete and will fully convey the aspects and features of the present disclosure to those skilled in the art.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, the term “and/or” includes any and all combinations of one or more of the associated listed items. For example, “A and/or B” indicates cases where it is A, or B, or both (e.g., simultaneously) A and B.

It will also be understood that if (e.g., when) a layer is referred to as being “on” another layer or substrate, it may be directly on the other layer or substrate, or intervening layers may also be present therebetween. In contrast, if (e.g., when) a layer is referred to as being “directly on” another layer or substrate, there are no intervening layers present therebetween.

Throughout the present disclosure, the expression “at least one of a, b, or c” indicates only a, only b, only c, both (e.g., simultaneously) a and b, both (e.g., simultaneously) a and c, both (e.g., simultaneously) b and c, all of a, b, and c, or variations thereof.

The same reference numbers indicate substantially the same components throughout the specification. In the attached drawings, the thickness of layers and regions may be exaggerated for clarity.

Although the terms “first”, “second”, and/or the like may be used herein to describe one or more suitable elements, these elements should not be limited by these terms. These terms may be used to distinguish one element from another element. Thus, a first element discussed herein may be termed a second element without departing from the scope of the present disclosure. The description of an element as a “first” element may not require or imply the presence of a second element or other elements. The terms “first”, “second”, and/or the like may also be used herein to differentiate different categories or sets of elements. For conciseness, the terms “first”, “second”, and/or the like may represent “first-category (or first-set)”, “second-category (or second-set)”, and/or the like, respectively.

In the following embodiments, terms, such as “include” or “have” refer to that features or components as described in the specification exist and do not preclude the possibility that one or more other features or components may be added. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the term “about” or similar terms are used as terms of approximation and not as terms of degree and are intended to account for the inherent deviations in measured or calculated values that may be recognized by those of ordinary skill in the art. The term “about” or “approximately,” as used herein, is also inclusive of the stated value and refers to within an acceptable range of deviation for the particular value as determined by one of ordinary skill in the art, considering the measurement in question and the error associated with measurement of the particular quantity (e.g., the limitations of the measurement system). For example, “about” may refer to within one or more standard deviations, or within ±30%, ±20%, ±10%, or ±5% of the stated value.

Any numerical range recited herein is intended to include all sub-ranges of substantially the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend the present disclosure, including the appended claims, to expressly recite any sub-range subsumed within the ranges expressly recited herein.

In the present disclosure, if (e.g., when) one or more suitable components, such as a layer, a film, a region, a plate, and/or the like, are described as being “on” another component, this includes not only the case where they are “directly on” the other component but also the case where another component is present therebetween. In contrast, if (e.g., when) a component is referred to as being “directly on” another component, there are no intervening components present therebetween.

Features of one or more embodiments of the present disclosure may be combined partially or totally. As will be clearly appreciated by those skilled in the art, one or more suitable interactions and operations may be feasible. One or more embodiments may be practiced individually or in combination.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if (e.g., when) the device in the drawings is turned over, elements as described as “below” or “beneath” or “under” other elements or features may then be oriented “above” the other elements or features. Thus, the example terms “below” and “under” may encompass both (e.g., simultaneously) an orientation of above and below. The device may be otherwise oriented (e.g., rotated 90 degrees or at other orientations) and the spatially relative descriptors used herein should be interpreted accordingly.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

Hereinafter, example embodiments will be described in more detail with reference to the accompanying drawings.

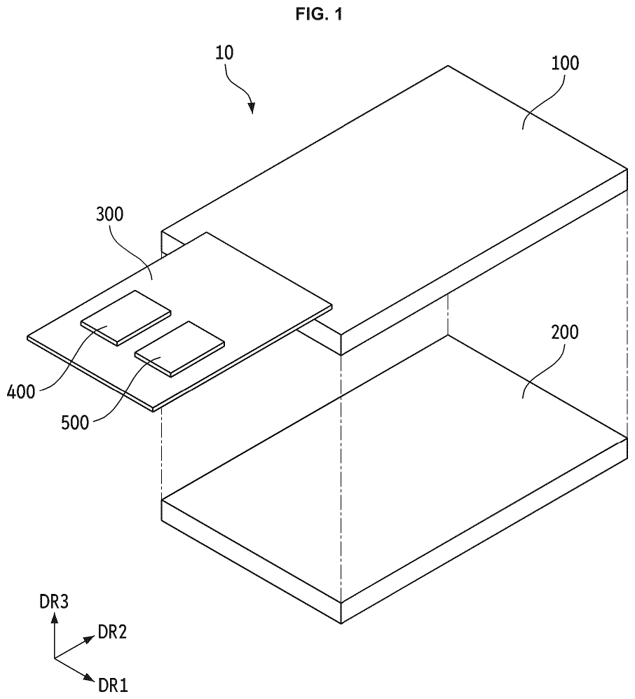

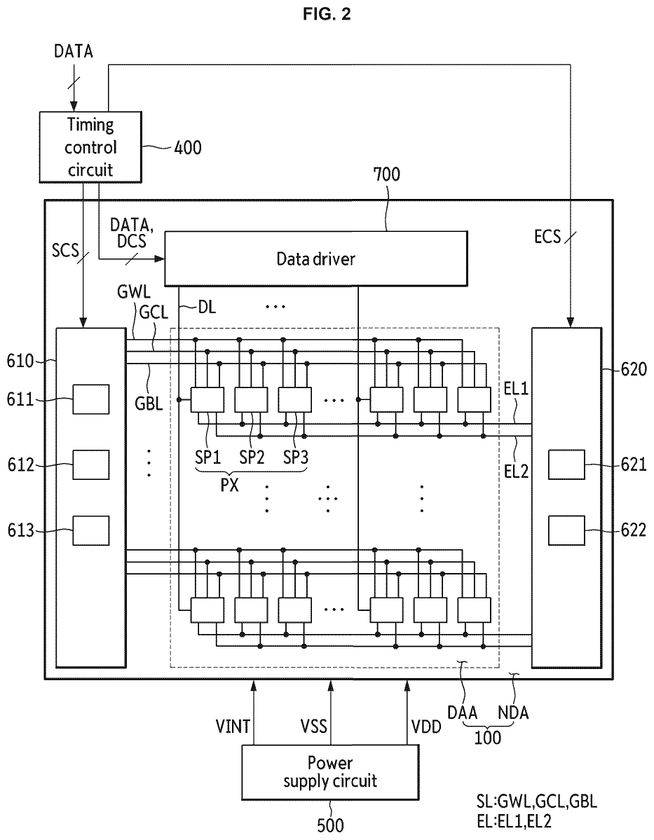

FIG. 1 is an exploded perspective view illustrating a display device according to one or more embodiments. FIG. 2 is a block diagram illustrating a display device according to one or more embodiments.

Referring to FIGS. 1 and 2, a display device 10 according to one or more embodiments is a device to display a moving image and/or a still image. The display device 10 according to one or more embodiments may be applied to portable electronic devices, such as a mobile phone, a smartphone, a tablet personal computer, a mobile communication terminal, an electronic organizer, an electronic book, a portable multimedia player (PMP), a navigation system, an ultra mobile PC (UMPC), and/or the like. For example, the display device 10 according to one or more embodiments may be applied as a display unit of a television, a laptop, a monitor, a billboard, or an Internet-of-Things (IoT) terminal. In one or more embodiments, the display device 10 according to one or more embodiments may be applied to a smart watch, a watch phone, a head mounted display (HMD) to implement virtual reality and/or augmented reality, and/or the like.

The display device 10 according to one or more embodiments may include a display panel 100, a heat dissipation layer 200, a circuit board 300, a timing control circuit 400, and a power supply circuit 500.

The display panel 100 may have a planar shape (e.g., a substantially planer shape) similar to a quadrilateral shape (e.g., a substantially quadrilateral shape). For example, the display panel 100 may have a planar shape (e.g., a substantially planer shape) similar to a quadrilateral shape (e.g., a substantially quadrilateral shape), having a short side of a first direction DR1 and a long side of a second direction DR2 intersecting the first direction DR1. In the display panel 100, a corner where a short side in the first direction DR1 and a long side in the second direction DR2 meet may be right-angled or rounded with a set or predetermined curvature. The planar shape of the display panel 100 is not limited to a quadrilateral shape (e.g., a substantially quadrilateral shape) and may be a shape similar to another polygonal shape (e.g., substantially polygonal shape), a circular shape (e.g., a substantially circular shape), or an elliptical shape (e.g., a substantially elliptical shape). The planar shape of the display device 10 may conform to the planar shape of the display panel 100, but embodiments of the present disclosure are not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA to display an image and a non-display area NDA not to display an image as illustrated in FIG. 2.

The plurality of pixels PX may be arranged in the display area DAA. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

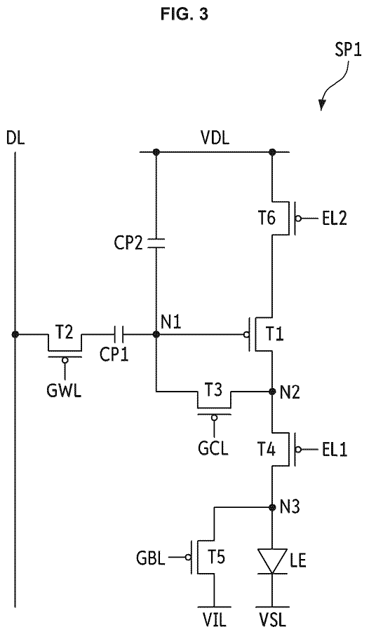

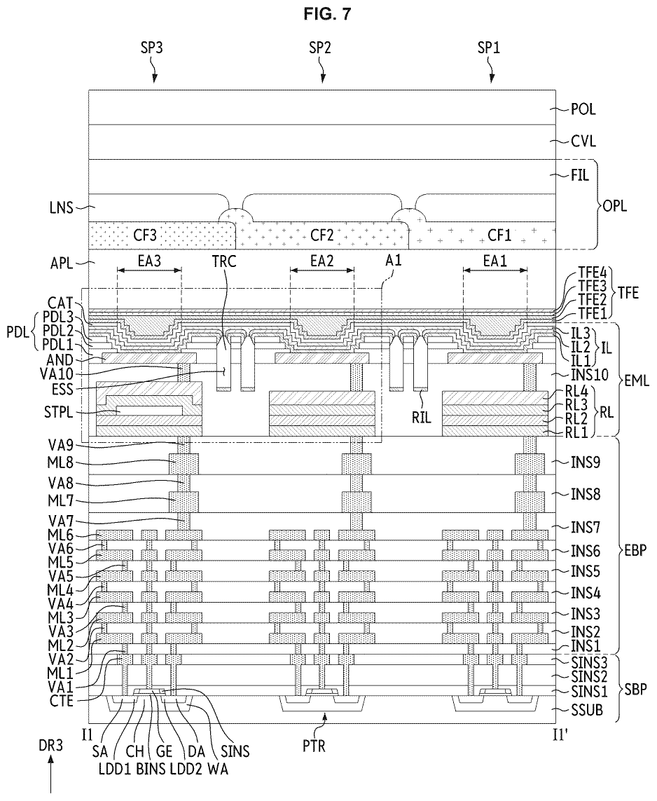

The plurality of pixels PX may include a plurality of sub-pixels SP1, SP2, and SP3. The plurality of sub-pixels SP1, SP2, and SP3 may include a plurality of pixel transistors as illustrated in FIG. 3, and the plurality of pixel transistors may be formed or arranged by a semiconductor process and arranged on a semiconductor substrate SSUB (see FIG. 7). For example, the plurality of pixel transistors of the data driver 700 may be formed or composed of complementary metal oxide semiconductor (CMOS), but embodiments of the present disclosure are not limited thereto.

Each of the plurality of sub-pixels SP1, SP2, and SP3 may be connected to any one write scan line GWL selected from among the plurality of write scan lines GWL, any one control scan line GCL selected from among the plurality of control scan lines GCL, any one bias scan line GBL selected from among the plurality of bias scan lines GBL, any one first emission control line EL1 selected from among the plurality of first emission control lines EL1, any one second emission control line EL2 selected from among the plurality of second emission control lines EL2, and any one data line DL selected from among the plurality of data lines DL. Each of the plurality of sub-pixels SP1, SP2, and SP3 may be to receive a data voltage of the data line DL in response to a write scan signal of the write scan line GWL and emit light from the light emitting element according to the data voltage.

The scan driver 610, the emission driver 620, and the data driver 700 may be arranged in the non-display area NDA.

The scan driver 610 may include a plurality of scan transistors, and the emission driver 620 may include a plurality of light emitting transistors. The plurality of scan transistors and the plurality of light emitting transistors may be formed or arranged on the semiconductor substrate SSUB (see FIG. 7) through a semiconductor process. For example, the plurality of scan transistors and the plurality of light emitting transistors may be formed or composed of CMOS, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may be to receive a scan timing control signal SCS from the timing control circuit 400. The write scan signal output unit 611 may be to generate write scan signals according to the scan timing control signal SCS of the timing control circuit 400 and output them sequentially to the write scan lines GWL. The control scan signal output unit 612 may be to generate control scan signals in response to the scan timing control signal SCS and sequentially output them to the control scan lines GCL. The bias scan signal output unit 613 may be to generate bias scan signals according to the scan timing control signal SCS and output them sequentially to the bias scan lines GBL.

The emission driver 620 may include a first emission control driver 621 and a second emission control driver 622. Each of the first emission control driver 621 and the second emission control driver 622 may be to receive an emission timing control signal ECS from the timing control circuit 400. The first emission control driver 621 may be to generate first emission control signals according to the emission timing control signal ECS and sequentially output them to the first emission control lines EL1. The second emission control driver 622 may be to generate second emission control signals according to the emission timing control signal ECS and sequentially output them to the second emission control lines EL2.

The data driver 700 may include a plurality of data transistors, and the plurality of data transistors may be formed or arranged on the semiconductor substrate SSUB (see FIG. 7) through a semiconductor process. For example, the plurality of data transistors may be formed or composed of CMOS, but embodiments of the present disclosure are not limited thereto.

The data driver 700 may be to receive digital video data DATA and a data timing control signal DCS from the timing control circuit 400. The data driver 700 may be to convert the digital video data DATA into analog data voltages according to the data timing control signal DCS and output the analog data voltages to data lines DL. In one or more embodiments, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be arranged on one surface of the display panel 100, for example, on the rear surface thereof. The heat dissipation layer 200 may act or serve to dissipate heat generated from the display panel 100. The heat dissipation layer 200 may include a metal layer having high thermal conductivity, such as graphite, silver (Ag), copper (Cu), and/or aluminum (Al).

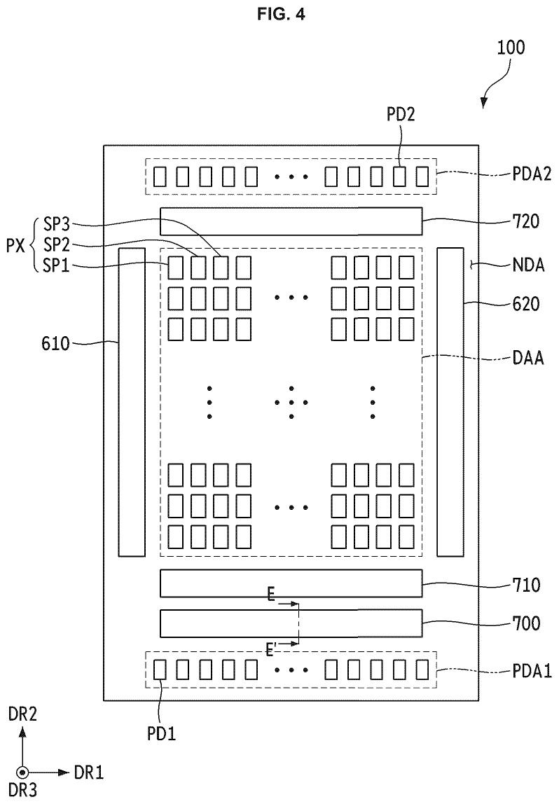

The circuit board 300 may be electrically connected to a plurality of first pads PD1 (see FIG. 4) of a first pad portion PDA1 (see FIG. 4) of the display panel 100 by utilizing a conductive (e.g., electrically conductive) adhesive member, such as an anisotropic conductive film. The circuit board 300 may be a flexible printed circuit board with a flexible material and/or a flexible film. Although the circuit board 300 is illustrated in FIG. 1 as being unfolded, the circuit board 300 may be bent. In one or more embodiments, one end of the circuit board 300 may be arranged on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by utilizing a conductive (e.g., electrically conductive) adhesive member. One end of the circuit board 300 may be an opposite end of the other end of the circuit board 300.

The timing control circuit 400 may be to receive digital video data and timing signals inputted from the outside. The timing control circuit 400 may be to generate the scan timing control signal SCS, the emission timing control signal ECS, and the data timing control signal DCS to control the display panel 100 in response to the timing signals. The timing control circuit 400 may be to output the scan timing control signal SCS to the scan driver 610 and output the emission timing control signal ECS to the emission driver 620. The timing control circuit 400 may be to output the digital video data and the data timing control signal DCS to the data driver 700.

The power supply circuit 500 may be to generate a plurality of panel driving voltages according to a power voltage from the outside. For example, the power supply circuit 500 may be to generate a first driving voltage VSS, a second driving voltage VDD, and a third driving voltage VINT and supply them to the display panel 100. The first driving voltage VSS, the second driving voltage VDD, and the third driving voltage VINT will be described in more detail herein in conjunction with FIG. 3.

Each of the timing control circuit 400 and the power supply circuit 500 may be formed or arranged as an integrated circuit (IC) and attached to one surface of the circuit board 300. In one or more embodiments, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In one or more embodiments, each of the timing control circuit 400 and the power supply circuit 500 may be arranged in the non-display area NDA of the display panel 100, similarly to the scan driver 610, the emission driver 620, and the data driver 700. In one or more embodiments, the timing control circuit 400 may include a plurality of timing transistors, and each power supply circuit 500 may include a plurality of power transistors. The plurality of timing transistors and the plurality of power transistors may be formed or arranged on the semiconductor substrate SSUB (see FIG. 7) through a semiconductor process. For example, the plurality of timing transistors and the plurality of power transistors may be formed or composed of CMOS, but embodiments of the present disclosure are not limited thereto. Each of the timing control circuit 400 and the power supply circuit 500 may be arranged between the data driver 700 and the first pad portion PDA1 (see FIG. 4).

FIG. 3 is an equivalent circuit diagram of a first sub-pixel according to one or more embodiments.

Referring to FIG. 3, a first sub-pixel SP1 may be connected to the write scan line GWL, the control scan line GCL, the bias scan line EBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. In one or more embodiments, the first driving voltage VSS may be lower than the third driving voltage VINT. The second driving voltage VDD may be higher than the third driving voltage VINT.

The first sub-pixel SP1 may include a plurality of transistors T1 to T6, a light emitting element LE, a first capacitor CP1, and a second capacitor CP2.

The light emitting element LE may be to emit light in response to a driving current flowing through the channel of the first transistor T1. The emission amount of the light emitting element LE may be proportional to the driving current Ids. The light emitting element LE may be arranged between a fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer arranged between the first electrode and the second electrode, but embodiments of the present disclosure are not limited thereto. For example, the light emitting element LE may be an inorganic light emitting element including a first electrode, a second electrode, and an inorganic semiconductor arranged between the first electrode and the second electrode, in which case the light emitting element LE may be a micro light emitting diode.

The first transistor T1 may be a driving transistor that controls a source-drain current Ids (hereinafter referred to as “driving current”) flowing between the source electrode and the drain electrode thereof according to a voltage applied to the gate electrode thereof. The first transistor T1 may include a gate electrode connected to a first node N1, a source electrode connected to the drain electrode of a sixth transistor T6, and a drain electrode connected to a second node N2.

A second transistor T2 may be arranged between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be arranged between the first node N1 and the second node N2. The third transistor T3 may be turned on by the write control signal of the write control line GCL to connect the first node N1 to the second node N2. For this reason, if (e.g., when) the gate electrode and the source electrode of the first transistor T1 are connected, the first transistor T1 may operate like a diode. The third transistor T3 may include a gate electrode connected to the write control line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

A fifth transistor T5 may be arranged between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line EBL, a source electrode connected to the third node N3, and a drain electrode connected to the third driving voltage line VIL.

The sixth transistor T6 may be arranged between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be formed or arranged between the first node N1 and the drain electrode of the second transistor T2. The first capacitor CP1 may include one electrode connected to the drain electrode of the second transistor T2 and the other electrode connected to the first node N1.

The second capacitor CP2 may be formed or arranged between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 may be a junction between the gate electrode of the first transistor T1, the drain electrode of the third transistor T3, the other electrode of the first capacitor CP1, and the one electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a positive type (kind) MOSFET (e.g., a P-type (kind) MOSFET), but embodiments of the present disclosure are not limited thereto. Each of the first to sixth transistors T1 to T6 may be a negative type (kind) MOSFET (e.g., an N-type (kind) MOSFET). In one or more embodiments, one or more of the first to sixth transistors T1 to T6 may be P-type (kind) MOSFETs, and each of the remaining transistors may be an N-type (kind) MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that as illustrated in FIG. 3. For example, the number of transistors and the number of capacitors of the first sub-pixel SP1 are not limited to those as illustrated in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 as described in conjunction with FIG. 3. Therefore, the description of the equivalent circuit diagram of the second sub-pixel SP2 and the equivalent circuit diagram of the third sub-pixel SP3 may not be repeated in the present disclosure.

FIG. 4 is a layout diagram illustrating an example of a display panel according to one or more embodiments.

Referring to FIG. 4, the display area DAA of the display panel 100 according to one or more embodiments may include the plurality of pixels PX arranged in a matrix form. The non-display area NDA of the display panel 100 according to one or more embodiments may include the scan driver 610, the emission driver 620, the data driver 700, a first distribution circuit 710, a second distribution circuit 720, the first pad portion PDA1, and a second pad portion PDA2.

The scan driver 610 may be arranged on the first side of the display area DAA, and the emission driver 620 may be arranged on the second side of the display area DAA. For example, the scan driver 610 may be arranged on one side of the display area DAA in the first direction DR1, and the emission driver 620 may be arranged on the other side of the display area DAA in the first direction DR1. For example, the scan driver 610 may be arranged on the left side of the display area DAA, and the emission driver 620 may be arranged on the right side of the display area DAA. However, embodiments of the present disclosure are not limited thereto, and the scan driver 610 and the emission driver 620 may be arranged on both (e.g., simultaneously) the first side and the second side of the display area DAA.

The first pad portion PDA1 may include the plurality of first pads PD1 connected to pads or bumps of the circuit board 300 through a conductive (e.g., electrically conductive) adhesive member. The first pad portion PDA1 may be arranged on the third side of the display area DAA. For example, the first pad portion PDA1 may be arranged on one side of the display area DAA in the second direction DR2. The first pad portion PDA1 may be arranged outside the data driver 700 in the second direction DR2. For example, the first pad portion PDA1 may be arranged closer to the edge of the display panel 100 than the data driver 700.

The second pad portion PDA2 may include a plurality of second pads PD2 corresponding to inspection pads that are to test whether the display panel 100 operates normally. The plurality of second pads PD2 may be connected to a jig or a probe pin during an inspection process or may be connected to a circuit board for inspection. The circuit board for inspection may be a printed circuit board made of a rigid material or a flexible printed circuit board made of a flexible material.

The second pad portion PDA2 may be arranged on the fourth side of the display area DAA. For example, the second pad portion PDA2 may be arranged on the other side of the display area DAA in the second direction DR2. The second pad portion PDA2 may be arranged outside the second distribution circuit 720 in the second direction DR2. For example, the second pad portion PDA2 may be arranged closer to the edge of the display panel 100 than the second distribution circuit 720.

The first distribution circuit 710 may be to distribute data voltages applied through the first pad portion PDA1 to the plurality of data lines DL. For example, the first distribution circuit 710 may be to distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be arranged on the third side of the display area DAA of the display panel 100. For example, the first distribution circuit 710 may be arranged on one side of the display area DAA in the second direction DR2. For example, the first distribution circuit 710 may be arranged on the lower side of the display area DAA.

The second distribution circuit 720 may be to distribute signals applied through the second pad portion PDA2 to the scan driver 610, the emission driver 620, and the data lines DL. The second pad portion PDA2 and the second distribution circuit 720 may be configured or arranged to inspect the operation of each of the pixels PX in the display area DAA. The second distribution circuit 720 may be arranged on the fourth side of the display area DAA of the display panel 100. For example, the second distribution circuit 720 may be arranged on the other side of the display area DAA in the second direction DR2. For example, the second distribution circuit 720 may be arranged on the upper side of the display area DAA.

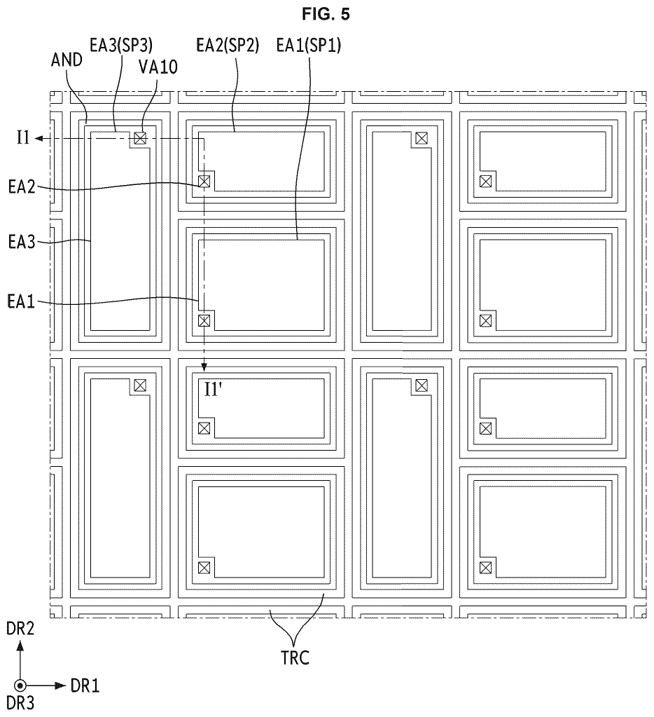

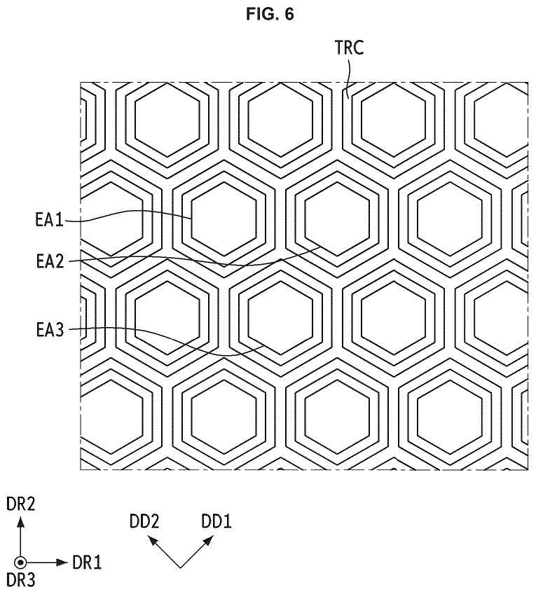

FIGS. 5 and 6 are layout diagrams illustrating examples of the display area of FIG. 4.

Referring to FIGS. 5 and 6, each of the pixels PX may include the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have a polygonal shape (e.g., a substantially polygonal shape), a circular shape (e.g., a substantially circular shape), an elliptical shape (e.g., a substantially elliptical shape), or atypical shape in plan view.

The maximum length of the first emission area EA1 in the first direction DR1 may be less than the maximum length of the second emission area EA2 in the first direction DR1 and the maximum length of the third emission area EA3 in the first direction DR1. The maximum length of the second emission area EA2 in the first direction DR1 and the maximum length of the third emission area EA3 in the first direction DR1 may be substantially the same.

The maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be less than the maximum length of the third emission area EA3 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have, in plan view, a hexagonal shape (e.g., a substantially hexagonal shape) formed or composed of six straight lines as illustrated in FIGS. 5 and 6, but embodiments of the present disclosure are not limited thereto. The first emission area EA1, the second emission area EA2, and the third emission area EA3 may have a polygonal shape (e.g., a substantially polygonal shape) other than a hexagonal shape (e.g., a substantially hexagonal shape), a circular shape (e.g., a substantially circular shape), an elliptical shape (e.g., a substantially elliptical shape), or an atypical shape in plan view.

As illustrated in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In one or more embodiments, the second emission area EA2 and the third emission area EA3 may be adjacent to each other in the second direction DR2. The area of the first emission area EA1, the area of the second emission area EA2, and the area of the third emission area EA3 may be different.

In one or more embodiments, as illustrated in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2 and may refer to a direction inclined by 45 degrees with respect to the first direction DR1 and the second direction DR2, and the second diagonal direction DD2 may be a direction normal (e.g., perpendicular) to the first diagonal direction DD1.

The first emission area EA1 may be to emit light of a first color, the second emission area EA2 may be to emit light of a second color, and the third emission area EA3 may be to emit light of a third color. In one or more embodiments, the first color light may be light of a blue wavelength band, the second color light may be light of a green wavelength band, and the third color light may be light of a red wavelength band. For example, the blue wavelength band may be a wavelength band of light whose main or predominant peak wavelength is in the range of about 370 nm to about 460 nm, the green wavelength band may be a wavelength band of light whose main or predominant peak wavelength is in the range of about 480 nm to about 560 nm, and the red wavelength band may be a wavelength band of light whose main or predominant peak wavelength is in the range of about 600 nm to about 750 nm.

It is exemplified in FIGS. 5 and 6 that each of the plurality of pixels PX may include three emission areas EA1, EA2, and EA3, but embodiments of the present disclosure are not limited thereto. For example, each of the plurality of pixels PX may include four emission areas.

In one or more embodiments, the layout of the emission areas of the plurality of pixels PX is not limited to those as illustrated in FIGS. 5 and 6. For example, the emission areas of the plurality of pixels PX may be arranged in a stripe structure (e.g., a substantially stripe structure) in which the emission areas are arranged in the first direction DR1, a PENTILE® structure (e.g., an RGBG matrix, an RGBG structure, or an RGBG matrix structure) in which the emission areas are arranged in a diamond shape (e.g., a substantially diamond shape), or a hexagonal structure (e.g., a substantially hexagonal structure) in which the emission areas having, in plan view, a hexagonal shape (e.g., a substantially hexagonal shape) are arranged as illustrated in FIG. 6. PENTILE® is a duly registered trademark of Samsung Display Co., Ltd.

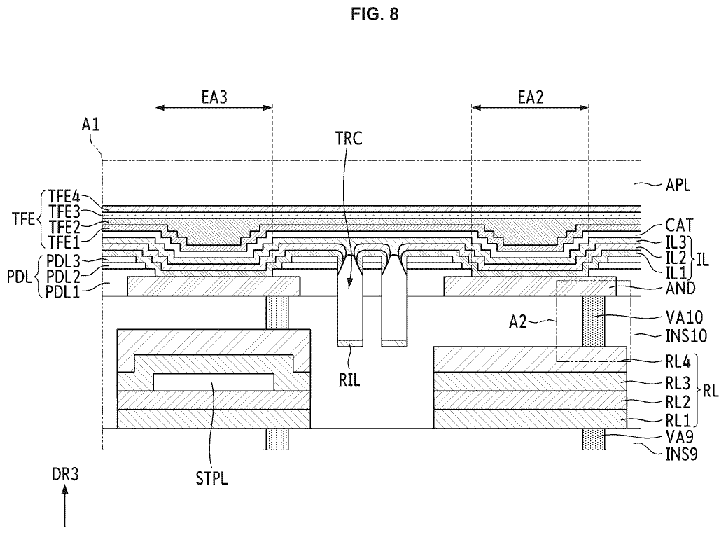

FIG. 7 is a cross-sectional view illustrating an example of a display panel taken along the line I1-I1′ of FIG. 5. FIG. 8 is a cross-sectional view illustrating area A1 of FIG. 7 in more detail.

Referring to FIGS. 7 and 8, the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include a semiconductor substrate SSUB including a plurality of pixel transistors PTR, a plurality of semiconductor insulating (e.g., electrically insulating) layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 as described with reference to FIG. 3.

The semiconductor substrate SSUB may be a silicon substrate, a germanium substrate, or a silicon-germanium substrate. The semiconductor substrate SSUB may be a substrate doped with a first type (kind) impurity. A plurality of well regions WA may be arranged on the top surface of the semiconductor substrate SSUB. The plurality of well regions WA may be regions doped with a second type (kind) impurity. The second type (kind) impurity may be different from the first type (kind) impurity as described in one or more embodiments. For example, if (e.g., when) the first type (kind) impurity is a positive type (kind) impurity (e.g., a p-type (kind) impurity), the second type (kind) impurity may be a negative type (kind) impurity (e.g., an n-type (kind) impurity). In one or more embodiments, if (e.g., when) the first type (kind) impurity is an n-type (kind) impurity, the second type (kind) impurity may be a p-type (kind) impurity.

Each of the plurality of well regions WA may include a source region SA corresponding to the source electrode of the pixel transistor PTR, a drain region DA corresponding to the drain electrode thereof, and a channel region CH arranged between the source region SA and the drain region DA.

A lower insulating layer BINS may be arranged between a gate electrode GE and the well region WA. A side insulating layer SINS may be arranged on the side surface of the gate electrode GE. The side insulating layer SINS may be arranged on the lower insulating layer BINS.

Each of the source region SA and the drain region DA may be a region doped with the first type (kind) impurity. The gate electrode GE of the pixel transistor PTR may overlap the well region WA in the third direction DR3. The channel region CH may overlap the gate electrode GE in the third direction DR3. The source region SA may be arranged on one side of the gate electrode GE, and the drain region DA may be arranged on the other side of the gate electrode GE.

Each of the plurality of well regions WA may further include a first low-concentration impurity region LDD1 arranged between the channel region CH and the source region SA and a second low-concentration impurity region LDD2 arranged between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that may be caused by a short channel may be prevented (or a degree or occurrence of punch-through and hot carrier phenomena that may be caused by a short channel may be reduced.

A first semiconductor insulating layer SINS1 may be arranged on the semiconductor substrate SSUB. The first semiconductor insulating layer SINS1 may be formed or composed of a silicon carbonitride (SiCN)-based inorganic film and/or a silicon oxide (e.g., SiOₓ, wherein 0<x≤2; e.g., SiO₂)-based inorganic film, but embodiments of the present disclosure are not limited thereto.

A second semiconductor insulating layer SINS2 may be arranged on the first semiconductor insulating layer SINS1. The second semiconductor insulating layer SINS2 may be formed or composed of a silicon oxide (e.g., SiOₓ, wherein 0<x≤2; e.g., SiO₂)-based inorganic film, but embodiments of the present disclosure are not limited thereto.

The plurality of contact terminals CTE may be arranged on the second semiconductor insulating layer SINS2. Each of the plurality of contact terminals CTE may be connected to any one selected from among the gate electrode GE, the source region SA, and the drain region DA of each of the pixel transistors PTR through holes penetrating the first semiconductor insulating layer SINS1 and the second semiconductor insulating layer INS2. The plurality of contact terminals CTE may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them.

A third semiconductor insulating layer SINS3 may be arranged on a side surface of each of the plurality of contact terminals CTE. The top surface of each of the plurality of contact terminals CTE may be exposed without being covered by the third semiconductor insulating layer SINS3. The third semiconductor insulating layer SINS3 may be formed or composed of a silicon oxide (e.g., SiOₓ, wherein 0<x≤2; e.g., SiO₂)-based inorganic film, but embodiments of the present disclosure are not limited thereto.

The semiconductor substrate SSUB may be replaced with a glass substrate and/or a polymer resin substrate, such as polyimide. In one or more embodiments, thin film transistors may be arranged on the glass substrate and/or the polymer resin substrate. The glass substrate may be a rigid substrate that does not bend, and the polymer resin substrate may be a flexible substrate that may be bent or curved.

The light emitting element backplane EBP may include a plurality of conductive layers ML1 to ML8, a plurality of vias VA1 to VA9, and a plurality of insulating layers INS1 to INS11. In one or more embodiments, the light emitting element backplane EBP may include a plurality of insulating layers INS1 to INS11 arranged between the first to eighth conductive layers ML1 to ML8.

The first to eighth conductive layers ML1 to ML8 may act or serve to connect the plurality of contact terminals CTE exposed from the semiconductor backplane SBP to thereby implement the circuit of the first sub-pixel SP1 as illustrated in FIG. 3. For example, the first to sixth transistors T1 to T6 may be formed or arranged in the semiconductor backplane SBP, and the connection of the first to sixth transistors T1 to T6 and the first and second capacitors C1 and C2 may be accomplished through the first to eighth conductive layers ML1 to ML8. In one or more embodiments, the connection between the drain region corresponding to the drain electrode of the fourth transistor T4, the source region corresponding to the source electrode of the fifth transistor T5, and a first electrode AND of the light emitting element LE may also be accomplished through the first to eighth conductive layers ML1 to ML8.

A first insulating layer INS1 may be arranged on the semiconductor backplane SBP. Each of first vias VA1 may penetrate the first insulating layer INS1 to be connected to the contact terminal CTE exposed from the semiconductor backplane SBP. Each of first conductive layers ML1 may be arranged on the first insulating layer INS1 and may be connected to the first via VA1.

A second insulating layer INS2 may be arranged on the first insulating layer INS1 and the first conductive layers ML1. Each of second vias VA2 may penetrate the second insulating layer INS2 and be connected to the exposed first conductive layer ML1. Each of second conductive layers ML2 may be arranged on the second insulating layer INS2 and may be connected to the second via VA2.

A third insulating layer INS3 may be arranged on the second insulating layer INS2 and the second conductive layers ML2. Each of third vias VA3 may penetrate the third insulating layer INS3 and be connected to the exposed second conductive layer ML2. Each of third conductive layers ML3 may be arranged on the third insulating layer INS3 and may be connected to the third via VA3.

A fourth insulating layer INS4 may be arranged on the third insulating layer INS3 and the third conductive layers ML3. Each of fourth vias VA4 may penetrate the fourth insulating layer INS4 and be connected to the exposed third conductive layer ML3. Each of fourth conductive layers ML4 may be arranged on the fourth insulating layer INS4 and may be connected to the fourth via VA4.

A fifth insulating layer INS5 may be arranged on the fourth insulating layer INS4 and the fourth conductive layers ML4. Each of fifth vias VA5 may penetrate the fifth insulating layer INS5 and be connected to the exposed fourth conductive layer ML4. Each of fifth conductive layers ML5 may be arranged on the fifth insulating layer INS5 and may be connected to the fifth via VA5.

A sixth insulating layer INS6 may be arranged on the fifth insulating layer INS5 and the fifth conductive layers ML5. Each of sixth vias VA6 may penetrate the sixth insulating layer INS6 and be connected to the exposed fifth conductive layer ML5. Each of sixth conductive layers ML6 may be arranged on the sixth insulating layer INS6 and may be connected to the sixth via VA6.

A seventh insulating layer INS7 may be arranged on the sixth insulating layer INS6 and the sixth conductive layers ML6. Each of seventh vias VA7 may penetrate the seventh insulating layer INS7 and be connected to the exposed sixth conductive layer ML6. Each of seventh conductive layers ML7 may be arranged on the seventh insulating layer INS7 and may be connected to the seventh via VA7.

An eighth insulating layer INS8 may be arranged on the seventh insulating layer INS7 and the seventh conductive layers ML7. Each of eighth vias VA8 may penetrate the eighth insulating layer INS8 and be connected to the exposed seventh conductive layer ML7. Each of eighth conductive layers ML8 may be arranged on the eighth insulating layer INS8 and may be connected to the eighth via VA8.

The first to eighth conductive layers ML1 to ML8 and the first to eighth vias VA1 to VA8 may be formed or composed of substantially the same material. The first to eighth conductive layers ML1 to ML8 and the first to eighth vias VA1 to VA8 may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. The first to eighth vias VA1 to VA8 may be formed or composed of substantially the same material. First to eighth insulating layers INS1 to INS8 may be formed or composed of a silicon oxide (e.g., SiOₓ, wherein 0<x≤2; e.g., SiO₂)-based inorganic film, but embodiments of the present disclosure are not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be about 1360 Å. The thickness of each of the second conductive layer ML2, the third conductive layer ML3, the fourth conductive layer ML4, the fifth conductive layer ML5, and the sixth conductive layer ML6 may be about 1440 Å. The thickness of each of the first via VA1, the second via VA2, the third via VA3, the fourth via VA4, the fifth via VA5, and the sixth via VA6 may be about 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be about 9,000 Å. The thickness of each of the seventh via VA7 and the eighth via VA8 may be about 6,000 Å.

A ninth insulating layer INS9 may be arranged on the eighth insulating layer INS8 and the eighth conductive layer ML8. The ninth insulating layer INS9 may be formed or composed of a silicon oxide (e.g., SiOₓ, wherein 0<x≤2; e.g., SiO₂)-based inorganic film, but embodiments of the present disclosure are not limited thereto.

Each of ninth vias VA9 may penetrate the ninth insulating layer INS9 and be connected to the exposed eighth conductive layer ML8. The ninth vias VA9 may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. The thickness of the ninth via VA9 may be about 16,500 Å.

The display element layer EML may be arranged on the light emitting element backplane EBP. The display element layer EML may include light emitting elements LE each including a reflective electrode layer RL, a tenth insulating layer INS10, a tenth via VA10, a first electrode AND, a light emitting stack IL, and a second electrode CAT; a pixel defining film PDL; and a plurality of trenches TRC.

The reflective electrode layer RL may be arranged on the ninth insulating layer INS9. The reflective electrode layer RL may include at least one reflective electrode RL1, RL2, RL3, and RL4 and a step layer STPL. For example, FIG. 7 illustrates that the one or more reflective electrodes RL1, RL2, RL3, and RL4 include first to fourth reflective electrodes RL1, RL2, RL3, and RL4, but embodiments of the present disclosure are not limited thereto.

Each of the first reflective electrodes RL1 may be arranged on the ninth insulating layer INS9 and may be connected to the ninth via VA9. The first reflective electrodes RL1 may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. For example, the first reflective electrodes RL1 may contain titanium nitride (TiN).

Each of the second reflective electrodes RL2 may be arranged on the first reflective electrode RL1. The second reflective electrodes RL2 may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. For example, the second reflective electrodes RL2 may include aluminum (Al).

In the third sub-pixel SP3, the step layer STPL may be arranged on the second reflective electrode RL2. The step layer STPL may not be arranged on the second reflective electrode RL2 in the second sub-pixel SP2 and the first sub-pixel SP1.

The thickness of the step layer STPL may be set or predetermined in consideration of the wavelength of the light of the first color and a distance from the light emitting stack IL of the third sub-pixel SP3 to the fourth reflective electrode RL4 to beneficially or advantageously reflect the light of the first color emitted from the light emitting stack IL.

The step layer STPL may be formed or composed of a silicon carbonitride (SiCN)-based inorganic film and/or a silicon oxide (e.g., SiOₓ, wherein 0<x≤2; e.g., SiO₂)-based inorganic film, but embodiments of the present disclosure are not limited thereto.

In the first sub-pixel SP1, the third reflective electrode RL3 may be arranged on the second reflective electrode RL2. In the second sub-pixel SP2, the third reflective electrode RL3 may be arranged on the second reflective electrode RL2. In the third sub-pixel SP3, the third reflective electrode RL3 may be arranged on the step layer STPL. The third reflective electrode RL3 may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. For example, the third reflective electrode RL3 may include titanium nitride (TiN).

At least one of the first reflective electrode RL1, the second reflective electrode RL2, or the third reflective electrode RL3 may not be provided.

The fourth reflective electrode RL4 may be arranged on the third reflective electrode RL3. The fourth reflective electrode RL4 may be a layer that reflects light from the light emitting stack IL. The fourth reflective electrode RL4 may include metal having high reflectivity to beneficially or advantageously reflect the light. In one or more embodiments, because the fourth reflective electrode RL4 is an electrode that substantially reflects light from the light emitting element LE, the thickness of the fourth reflective electrode RL4 may be greater than the thickness of each of the first reflective electrode RL1, the second reflective electrode RL2, and the third reflective electrode RL3. The fourth reflective electrode RL4 may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. For example, the fourth reflective electrodes RL4 may include aluminum (Al) and/or titanium (Ti).

The tenth insulating layer INS10 may be arranged on the ninth insulating layer INS9 and the fourth reflective electrodes RL4. The tenth insulating layer INS10 may be an optical auxiliary layer through which light reflected by the reflective electrode layer RL passes, among light emitted from the light emitting elements LE. The tenth insulating layer INS10 may be formed or composed of a silicon oxide (e.g., SiOₓ, wherein 0<x≤2; e.g., SiO₂) based inorganic film, but embodiments of the present disclosure are not limited thereto.

Each of the tenth vias VA10 may penetrate the tenth insulating layer INS10 and be connected to the exposed ninth metal layer ML9. The tenth vias VA10 may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them.

The thickness of the tenth via VA10 may vary in the first sub-pixel SP1, the second sub-pixel SP2, and the third sub-pixel SP3 in order to adjust a resonance distance of light emitted from the light emitting elements LE in at least one of the first sub-pixel SP1, the second sub-pixel SP2, or the third sub-pixel SP3. For example, the thickness of the tenth via VA10 in the third sub-pixel SP3 may be less than the thickness of the tenth via VA10 in each of the first sub-pixel SP1 and the second sub-pixel SP2. Further, the thickness of the tenth via VA10 in the second sub-pixel SP2 may be smaller than the thickness of the tenth via VA10 in the first sub-pixel SP1. For example, the distance between the light emitting stack IL and the reflective electrode layer RL may be different in the first sub-pixel SP1, the second sub-pixel SP2, and the third sub-pixel SP3.

In one or more embodiments, in order to adjust the distance between the light emitting stack IL and the reflective electrode layer RL according to the main or predominant wavelength of light emitted from the first sub-pixel SP1, the presence or absence of the step layer STPL and the thickness of the step layer STPL in the first sub-pixel SP1, the second sub-pixel SP2, and the third sub-pixel SP3 may be set or predetermined.

The first electrode AND of each of the light emitting elements LE may be arranged on the tenth insulating layer INS10 and connected to the tenth via VA10. The first electrode AND of each of the light emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed or composed of any one selected from among copper (Cu), aluminum (Al), tungsten (W), molybdenum (Mo), chromium (Cr), gold (Au), titanium (Ti), nickel (Ni), and neodymium (Nd), or an alloy including any one selected from among them. For example, the first electrode AND of each of the light emitting elements LE may be titanium nitride (TiN).

The pixel defining film PDL may be arranged on a part of the first electrode AND of each of the light emitting elements LE. The pixel defining film PDL may cover the edge of the first electrode AND of each of the light emitting elements LE. The pixel defining film PDL may act or serve to partition the first emission areas EA1, the second emission areas EA2, and the third emission areas EA3.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be arranged on the edge of the first electrode AND of each of the light emitting elements LE, the second pixel defining film PDL2 may be arranged on the first pixel defining film PDL1, and the third pixel defining film PDL3 may be arranged on the second pixel defining film PDL2. The first pixel defining film PDL1, the second pixel defining film PDL2, and the third pixel defining film PDL3 may be formed or composed of a silicon oxide (e.g., SiOₓ, wherein 0<x≤2; e.g., SiO₂)-based inorganic film, but embodiments of the present disclosure are not limited thereto. The first pixel defining film PDL1, the second pixel defining film PDL2, and the third pixel defining film PDL3 may each have a thickness of about 500 Å.

If (e.g., when) the first pixel defining film PDL1, the second pixel defining film PDL2, and the third pixel defining film PDL3 are formed or arranged as one pixel defining film, the height of the one pixel defining film may increase, so that a first encapsulation inorganic film TFE1 may be cut off due to step coverage. Step coverage refers to the ratio of the degree of thin film coated on an inclined portion to the degree of thin film coated on a flat portion. The lower the step coverage is, the more likely it is that the thin film may be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

Each of the plurality of trenches TRC may penetrate the first pixel defining film PDL1, the second pixel defining film PDL2, and the third pixel defining film PDL3. Further, the tenth insulating layer INS10 may be partially recessed at each of the plurality of trenches TRC.

At least one trench TRC may be arranged between the neighboring sub-pixels SP1, SP2, and SP3. Although FIG. 7 illustrates that two trenches TRC are arranged between adjacent sub-pixels SP1, SP2, and SP3, embodiments of the present disclosure are not limited thereto.

The light emitting stack IL may include a plurality of intermediate layers. FIG. 7 illustrates that the light emitting stack IL has a three-tandem structure including the first stack layer IL1, the second stack layer IL2, and the third stack layer IL3, but embodiments of the present disclosure are not limited thereto. For example, the light emitting stack IL may have a two-tandem structure including two stack layers.

In the three-tandem structure, the light emitting stack IL may have a tandem structure including a plurality of stack layers IL1, IL2, and IL3 that are to emit different lights. For example, the light emitting stack IL may include the first stack layer IL1 that is to emit light of the first color, the second stack layer IL2 that is to emit light of the third color, and the third stack layer IL3 that is to emit light of the second color. The first stack layer IL1, the second stack layer IL2, and the third stack layer IL3 may be sequentially stacked.

The first stack layer IL1 may have a structure in which a first hole transport layer, a first organic light emitting layer that is to emit light of the first color, and a first electron transport layer are sequentially stacked. The second stack layer IL2 may have a structure in which a second hole transport layer, a second organic light emitting layer that is to emit light of the third color, and a second electron transport layer are sequentially stacked. The third stack layer IL3 may have a structure in which a third hole transport layer, a third organic light emitting layer that is to emit light of the second color, and a third electron transport layer are sequentially stacked.

A first charge generation layer to supply charges to the second stack layer IL2 and supply electrons to the first stack layer IL1 may be arranged between the first stack layer IL1 and the second stack layer IL2. The first charge generation layer may include a negative type (kind) charge generation layer (e.g., an N-type (kind) charge generation layer) that is to supply electrons to the first stack layer IL1 and a positive type (kind) charge generation layer (e.g., a P-type (kind) charge generation layer) that is to supply holes to the second stack layer IL2. The N-type (kind) charge generation layer may include a dopant of a metal material.

A second charge generation layer to supply charges to the third stack layer IL3 and supply electrons to the second stack layer IL2 may be arranged between the second stack layer IL2 and the third stack layer IL3. The second charge generation layer may include an N-type (kind) charge generation layer that is to supply electrons to the second stack layer IL2 and a P-type (kind) charge generation layer that is to supply holes to the third stack layer IL3.

The first stack layer IL1 may be arranged on the first electrodes AND and the pixel defining film PDL. A remaining stack layer RIL made of substantially the same material as the first stack layer IL1 may be arranged on the bottom surface of each of the trenches TRC. Due to the trench TRC, the first stack layer IL1 may be cut off between the neighboring sub-pixels SP1, SP2, and SP3. The second stack layer IL2 may be arranged on the first stack layer IL1. Due to the trench TRC, the second stack layer IL2 may be cut off between the neighboring sub-pixels SP1, SP2, and SP3. A void ESS or an empty space may be arranged between the remaining stack layer RIL and the second stack layer IL2 in each trench TRC. The third stack layer IL3 may be arranged on the second stack layer IL2. The third stack layer IL3 may not be cut off by the trench TRC and may be arranged to cover the second stack layer IL2 in each of the trenches TRC. For example, in the three-tandem structure, each of the plurality of trenches TRC may be a structure to cut off the first to second stack layers IL1 and IL2, the first charge generation layer, and the second charge generation layer of the display element layer EML between the neighboring sub-pixels SP1, SP2, and SP3.

In one or more embodiments, in the two-tandem structure, each of the plurality of trenches TRC may be a structure to cut off the charge generation layer and the lower stack layer arranged between the lower stack layer and the upper stack layer.

In order to stably cut off the first stack layer IL1 of the display element layer EML between adjacent sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the first to third stack layers IL1, IL2, and IL3 of the display element layer EML between the neighboring sub-pixels SP1, SP2, and SP3, another structure may exist instead of the trench TRC. For example, instead of the trench TRC, a reverse tapered partition wall may be arranged on the pixel defining film PDL.

In one or more embodiments, FIGS. 7 and 8 illustrate that the first to third stack layers IL1, IL2, and IL3 are all arranged in the first emission area EA1, the second emission area EA2, and the third emission area EA3, but embodiments of the present disclosure are not limited thereto. For example, the first stack layer IL1 may be arranged in the first emission area EA1 and may not be provided in the second emission area EA2 and the third emission area EA3. Furthermore, the second stack layer IL2 may be arranged in the second emission area EA2 and may not be provided in the first emission area EA1 and the third emission area EA3. Further, the third stack layer IL3 may be arranged in the third emission area EA3 and may not be provided in the first emission area EA1 and the second emission area EA2. In one or more embodiments, first to third color filters CF1, CF2, and CF3 of the optical layer OPL may not be provided.

The second electrode CAT may be arranged on the third stack layer IL3. The second electrode CAT may be arranged on the third stack layer IL3 in each of the plurality of trenches TRC. The second electrode CAT may be formed or composed of a transparent (e.g., substantially transparent) conductive (e.g., electrically conductive) material (TCO), such as indium tin oxide (ITO) and/or indium zinc oxide (IZO), that may be to transmit light or a semi-transmissive conductive (e.g., electrically conductive) material, such as magnesium (Mg), silver (Ag), or an alloy of Mg and Ag. If (e.g., when) the second electrode CAT is formed or composed of a semi-transmissive conductive (e.g., electrically conductive) material, the light emission efficiency may be improved or enhanced in each of the first to third sub-pixels SP1, SP2, and SP3 due to a micro-cavity effect.

The encapsulation layer TFE may be arranged on the display element layer EML. The encapsulation layer TFE may include at least one inorganic film TFE1, TFE2, TFE3, TFE4, and TFE5 to prevent oxygen and/or moisture from permeating (or reduce a degree to or occurrence of which oxygen and/or moisture penetrate) into the display element layer EML. For example, the encapsulation layer TFE may include a first sub-encapsulation layer TFE1, a second sub-encapsulation layer TFE2, a third sub-encapsulation layer TFE3, and a fourth sub-encapsulation layer TFE4, which are sequentially stacked along the thickness direction (e.g., the third direction DR3) of the encapsulation layer TFE. In one or more embodiments, the first sub-encapsulation layer TFE1, the third sub-encapsulation layer TFE3, and the fourth sub-encapsulation layer TFE4 may each include an inorganic material, and the second sub-encapsulation layer TFE2 may include an organic material.

The first sub-encapsulation layer TFE1 may be arranged on the second electrode CAT. The first sub-encapsulation layer TFE1 may be formed or arranged as a multilayer in which one or more inorganic films selected from among silicon nitride (e.g., Si₃N₄ or SiNₓ, wherein 0<x≤2), silicon oxynitride (e.g., Si₂N₂O or SiOₓN_{y}, wherein 0<x≤2 and 0≤y≤2; e.g., SiON), and silicon oxide (e.g., SiOₓ, wherein 0<x≤2; e.g., SiO₂) are alternately stacked. The first sub-encapsulation layer TFE1 may be formed or arranged by a chemical vapor deposition (CVD) process. The thickness of the first sub-encapsulation layer TFE1 may be smaller than or equal to about 1 μm.

The second sub-encapsulation layer TFE2 may be arranged on the first sub-encapsulation layer TFE1. For example, the second sub-encapsulation layer TFE2 may be arranged between the first sub-encapsulation layer TFE1 and the third sub-encapsulation layer TFE3. The second sub-encapsulation layer TFE2 may be in contact (or direct contact) with each of the first sub-encapsulation layer TFE1 and the third sub-encapsulation layer TFE3. The second sub-encapsulation layer TFE2 may be an organic film of an organic resin, such as an acryl resin, an epoxy resin, a phenolic resin, a polyamide resin, a polyimide resin and/or the like.

The third sub-encapsulation layer TFE3 may be arranged on the second sub-encapsulation layer TFE2. For example, the third sub-encapsulation layer TFE3 may be arranged between the second sub-encapsulation layer TFE2 and the fourth sub-encapsulation layer TFE4. The third sub-encapsulation layer TFE3 may be in contact (or direct contact) with each of the second sub-encapsulation layer TFE2 and the fourth sub-encapsulation layer TFE4. The third sub-encapsulation layer TFE3 may be formed or arranged as a multilayer in which one or more inorganic films selected from among silicon nitride (e.g., Si₃N₄ or SiNₓ, wherein 0<x≤2), silicon oxynitride (e.g., Si₂N₂O or SiOₓN_{y}, wherein 0<x≤2 and 0≤y≤2; e.g., SiON), and silicon oxide (e.g., SiOₓ, wherein 0<x≤2; e.g., SiO₂) are alternately stacked. The third sub-encapsulation layer TFE3 may be formed or arranged by a chemical vapor deposition (CVD) process.

The fourth sub-encapsulation layer TFE4 may be arranged on the third sub-encapsulation layer TFE3. For example, the fourth sub-encapsulation layer TFE4 may be arranged between the third sub-encapsulation layer TFE3 and an organic layer APL. The fourth sub-encapsulation layer TFE4 may be in contact (or direct contact) with each of the third sub-encapsulation layer TFE3 and the organic layer APL. The fourth sub-encapsulation layer TFE4 may be arranged at the uppermost side among the sub-encapsulation layers TFE1 to TFE4 of the encapsulation layer TFE. The fourth sub-encapsulation layer TFE4 may be formed or composed of titanium oxide (e.g., TiOₓ, wherein 0<x≤2; e.g., TiO₂) and/or aluminum oxide (e.g., AlOₓ, wherein 0<x≤2; e.g., Al₂O₃), but embodiments of the present disclosure are not limited thereto. The fourth sub-encapsulation layer TFE4 may be formed or arranged by an atomic layer deposition (ALD) process.

The organic layer APL may be a layer to increase or enhance the interfacial adhesion between the encapsulation layer TFE and the optical layer OPL. The organic layer APL may be an organic film of an organic resin, such as an acrylic resin, an epoxy resin, a phenolic resin, a polyamide resin, and/or a polyimide resin.

The optical layer OPL may include a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be arranged on an adhesive layer ADL.

The first color filter CF1 may overlap the first emission area EA1 of the first sub-pixel SP1. The first color filter CF1 may be to transmit light of the first color, e.g., light of a red wavelength band. Thus, the first color filter CF1 may be to transmit light of the first color among light emitted from the first emission area EA1.

The second color filter CF2 may overlap the second emission area EA2 of the second sub-pixel SP2. The second color filter CF2 may be to transmit light of the second color, e.g., light of a green wavelength band. Thus, the second color filter CF2 may be to transmit light of the second color among light emitted from the second emission area EA2.

The third color filter CF3 may overlap the third emission area EA3 of the third sub-pixel SP3. The third color filter CF3 may be to transmit light of the third color, e.g., light of a blue wavelength band. Thus, the third color filter CF3 may be to transmit light of the third color among light emitted from the third emission area EA3.

The plurality of lenses LNS may be arranged on the first color filter CF1, the second color filter CF2, and the third color filter CF3, respectively. Each of the plurality of lenses LNS may be a structure to increase the proportion of light directed to the front of the display device 10. Although each of the lenses LNS is illustrated as having a cross-sectional shape that is convex upward, embodiments of the present disclosure are not limited thereto.

The filling layer FIL may be arranged on the plurality of lenses LNS. The filling layer FIL may have a set or predetermined refractive index such that light travels in the third direction DR3 at an interface between the filling layer FIL and the plurality of lenses LNS. Further, the filling layer FIL may be a planarization layer. The filling layer FIL may be an organic film of an organic resin, such as an acrylic resin, an epoxy resin, a phenolic resin, a polyamide resin, and/or a polyimide resin.

The cover layer CVL may be arranged on the filling layer FIL. The cover layer CVL may be a glass substrate and/or a polymer resin. If (e.g., when) the cover layer CVL is a glass substrate, it may be attached onto the filling layer FIL. In one or more embodiments, the filling layer FIL may act or serve to bond the cover layer CVL. If (e.g., when) the cover layer CVL is a glass substrate, it may act or serve as an encapsulation substrate. If (e.g., when) the cover layer CVL is a polymer resin, it may be directly applied onto the filling layer FIL.

The polarizing plate POL may be arranged on one surface of the cover layer CVL. The polarizing plate POL may be a structure to reduce or prevent visibility degradation (e.g., a degree or occurrence of visibility degradation) caused by reflection of external light. The polarizing plate POL may include a linear polarizing plate and a phase retardation film. For example, the phase retardation film may be a λ/4 plate (quarter-wave plate), but embodiments of the present disclosure are not limited thereto. However, if (e.g., when) visibility degradation caused by reflection of external light is sufficiently or suitably overcome by the first to third color filters CF1, CF2, and CF3, the polarizing plate POL may not be provided.

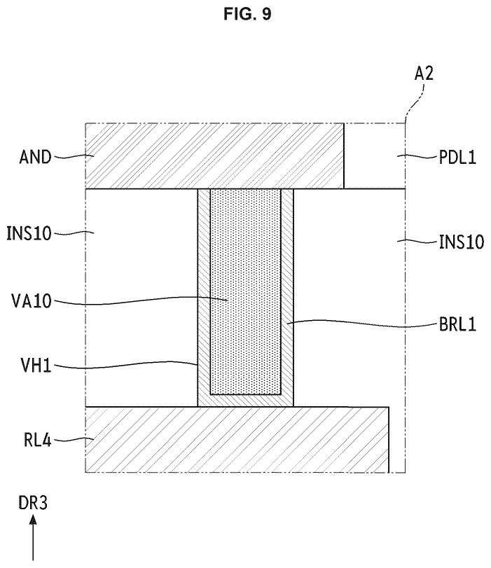

FIG. 9 is a cross-sectional view illustrating an example of area A2 of FIG. 8 in more detail.

As illustrated in FIG. 9, the tenth via VA10 may be arranged inside a first via hole VH1 of the tenth insulating layer INS10.

In one or more embodiments, a first barrier layer BRL1 may further be arranged in the first via hole VH1. For example, the first barrier layer BRL1 may be arranged between the first via hole VH1 and the tenth via VA10. For example, the first barrier layer BRL1 may be arranged between the inner wall of the first via hole VH1 and the tenth via VA10. In one or more embodiments, the first barrier layer BRL1 may be arranged even between the tenth via VA10 and the fourth electrode RL4. The first barrier layer BRL1 may be around (e.g., surround) the side surface of the tenth via VA10 inside the first via hole VH1. In a cross-sectional view, the tenth via VA10 may have a U-shaped cross-section. The first barrier layer BRL1 may be formed or composed of a material including titanium nitride (e.g., TiN_{X}, wherein 0<x≤2; e.g., TiN). For example, the first barrier layer BRL1 may be formed or composed of a titanium nitride (e.g., TiN_{X}, wherein 0<x≤2; e.g., TiN).

A first electrode AND may be arranged on the first barrier layer BRL1 and the tenth via VA10. As described in one or more embodiments, the first electrode AND may be formed or composed of titanium nitride (e.g., TiN_{X}, wherein 0<x≤2; e.g., TiN), and, in one or more embodiments, in a cross-sectional view, the tenth via VA10 may be surrounded by titanium nitride (e.g., TiN_{X}, wherein 0<x≤2; e.g., TiN). For example, the side, upper and the lower surfaces of the tenth via VA10 may be surrounded by the titanium nitride (e.g., TiN).

According to the display device 10 of one or more embodiments, because the first barrier layer BRL1 is formed or composed of only titanium nitride (e.g., TiN_{X}, wherein 0<x≤2; e.g., TiN), a permeation path of the cleaning solution into the fourth reflective electrode RL4 may not be formed or arranged in the forming process of the first via hole VH1. Accordingly, if (e.g., when) the fourth reflective electrode RL4 is formed or composed of a material including aluminum (Al), the fourth reflective electrode RL4 may be prevented from being damaged by the cleaning solution (or a degree to or occurrence of which the fourth reflective electrode RL4 is damaged by the cleaning solution may be reduced) used during the process of forming or arranging the first via hole VH1 and the tenth via VA10. For example, the fourth reflective electrode RL4 may be prevented from being melted by the cleaning solution (or a degree to or occurrence of which the fourth reflective electrode RL4 is melted by the cleaning solution may be reduced). For example, the tenth via VA10 is arranged inside the first via hole VH1 of the tenth insulating layer INS10. In one or more embodiments, the first barrier layer BRL1, formed or composed of titanium nitride (e.g., TiN_{X}, wherein 0<x≤2; e.g., TiN), may be arranged between the inner wall of the first via hole VH1 and the tenth via VA10, and even between the tenth via VA10 and the fourth electrode RL4. This barrier layer surrounds the side surface of the tenth via VA10 inside the first via hole VH1, providing protection. The first electrode AND, also formed or composed of titanium nitride, may be arranged on the first barrier layer BRL1 and the tenth via VA10, ensuring that the tenth via VA10 is surrounded by titanium nitride. This configuration prevents and/or blocks the formation of a permeation path for the cleaning solution into the fourth reflective electrode RL4, protecting it from damage and/or melting during the cleaning process.

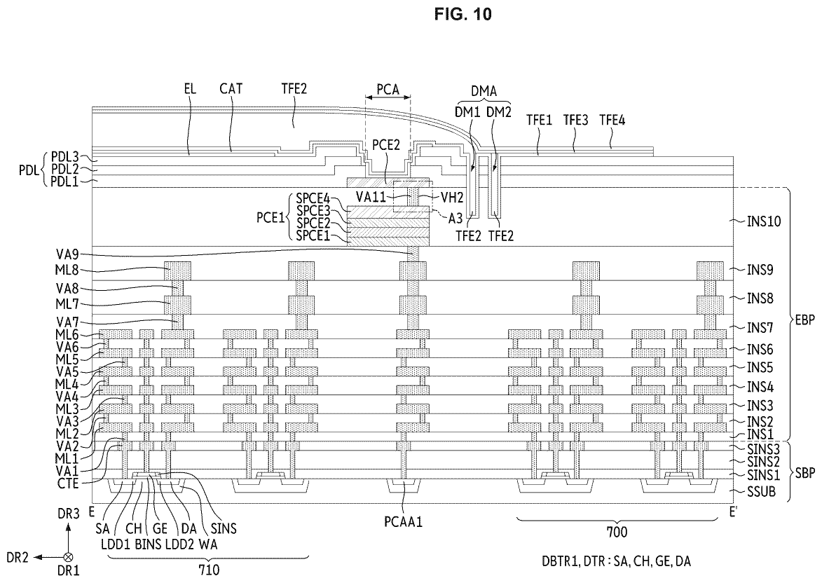

FIG. 10 is a cross-sectional view illustrating an example of a display panel cut along the line E-E′ of FIG. 4.

A first distribution circuit 710, a power connector PCA, a dam portion DMA, and a data driver 700 arranged on one side of the display area DA are illustrated in FIG. 10.

The first distribution circuit 710, the power connector PCA, the dam portion DMA, and the data driver 700 may be sequentially arranged in the second direction DR2 on one side of the display area DA. However, embodiments of the present disclosure are not limited thereto, and the power connector PCA may overlap the first distribution circuit 710 or the data driver 700 in the third direction DR3, and the dam portion DMA may overlap the first distribution circuit 710 or the data driver 700 in the third direction DR3.

The first distribution circuit 710 may include a plurality of first distribution transistors DBTR1. Because each of the plurality of first distribution transistors DBTR1 may be formed or arranged substantially the same as the pixel transistors PTR as described with reference to FIG. 7, more detailed description with respect to the plurality of first distribution transistors DBTR1 may not be provided. In one or more embodiments, because the first to eighth metal layers ML1 to ML8 and the first to eighth vias VA1 to VA8 electrically connected to the plurality of first distribution transistors DBTR1 are substantially the same as described with reference to FIG. 7, more detailed description with respect to thereof may not be provided.

The power connector PCA may include a first power connection area PCAA1 of the semiconductor substrate SSUB, a first power connection electrode PCE1, and a second power connection electrode PCE2.

A first driving voltage VSS may be applied to the first power connection area PCAA1 of the semiconductor substrate SSUB.

The first power connection electrode PCE1 may be arranged on the ninth insulating layer INS9. The first power connection electrode PCE1 may be connected to the first power connection area PCAA1 of the semiconductor substrate SSUB through the first to eighth metal layers ML1 to ML8 and the first to eighth vias VA1 to VA8.

The first power connection electrode PCE1 may include first to fourth sub-power connection electrodes SPCE1 to SPCE4. The first to fourth sub-power connection electrodes SPCE1 to SPCE4 of the first power connection electrode PCE1 may be substantially the same as the first to fourth reflective electrodes RL1 to RL4. For example, the first sub-power connection electrode SPCE1 may correspond to the first reflective electrode RL1, the second sub-power connection electrode SPCE2 may correspond to the second reflective electrode RL2, the third sub-power connection electrode SPCE3 may correspond to the third reflective electrode RL3, and the fourth sub-power connection electrode SPCE4 may correspond to the fourth reflective electrode RL4.

The second power connection electrode PCE2 may be arranged on the tenth insulating layer INS10. The second power connection electrode PCE2 may be connected to the first power connection electrode PCE1 through an eleventh via VA11. The second power connection electrode PCE2 may include substantially the same material as the first electrode AND of the light emitting element LE. The second power connection electrode PCE2 may be divided by the pixel defining film PDL. The second electrode CAT of the light emitting element LE may be connected to the second power connection electrode PCE2 that is not covered by the pixel defining film PDL and is exposed.

The dam portion DMA may include a first dam DM1 and a second dam DM2. The first dam DM1 and the second dam DM2 may be substantially the same as a trench TR. Each of the first dam DM1 and the second dam DM2 may penetrate a first pixel defining film PDL1, a second pixel defining film PDL2, and a third pixel defining film PDL3. A portion of the tenth insulating layer INS10 may be partially recessed at each of the first dam DM1 and the second dam DM2.

In each of the first dam DM1 and the second dam DM2, a first encapsulation inorganic film TFE1 may be arranged on the bottom surface, an encapsulation organic film TFE2 may be arranged on the first encapsulation inorganic film TFE1, and a second encapsulation inorganic film TFE3 may be arranged on the encapsulation organic film TFE2. The encapsulation organic film TFE2 may be arranged to fill a portion of each of the first dam DM1 and the second dam DM2. In one or more embodiments, the encapsulation organic film TFE2 may not be arranged on each of the first dam DM1 and the second dam DM2. For example, the first encapsulation inorganic film TFE1 and the second encapsulation inorganic film TFE3 may be arranged in each of the first dam DM1 and the second dam DM2.

The first dam DM1 and the second dam DM2 may prevent the encapsulation organic film TFE2 from flowing to the first pad portion PDA1 and covering the first pad PD1 (or reduce a degree to or occurrence of which the encapsulation organic film TFE2 flows to the first pad portion PDA1 and covers the first pad PD1). If (e.g., when) the encapsulation organic film TFE2 covers the first pads PD1, the first pads PD1 may not be electrically connected to the circuit board 300.

The data driver 700 may include a plurality of data transistors DTR. Because each of the plurality of data transistors DTR may be formed or arranged substantially the same as the pixel transistors PTR as described with reference to FIG. 7, more detailed description of the plurality of data transistors DTR may not be provided. In one or more embodiments, because the first to eighth metal layers ML1 to ML8 and the first to eighth vias VA1 to VA8 electrically connected to the plurality of data transistors DTR are substantially the same as described with reference to FIG. 7, more detailed description with respect to thereof may not be provided.

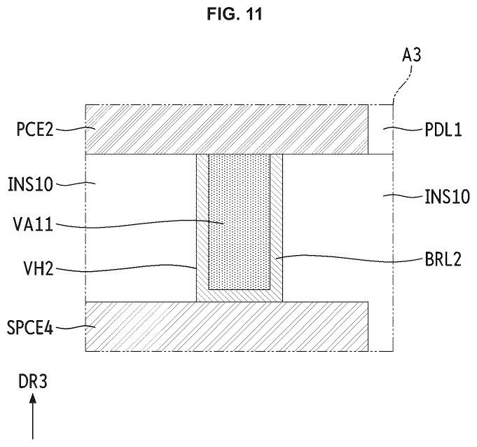

FIG. 11 is a cross-sectional view illustrating an example of area A3 of FIG. 10 in more detail.

As illustrated in FIG. 11, an eleventh via VA11 may be arranged in a second via hole VH2 of the tenth insulating layer INS10.

In one or more embodiments, a second barrier layer BRL2 may further be arranged in the second via hole VH2. For example, the second barrier layer BRL2 may be arranged between the second via hole VH2 and the eleventh via VA11. For example, the second barrier layer BRL2 may be arranged between the inner wall of the second via hole VH2 and the eleventh via VA11. In one or more embodiments, the second barrier layer BRL2 may be arranged even between the eleventh via VA11 and the fourth sub-power connection electrode SPCE4. The second barrier layer BRL2 may be around (e.g., surround) the side surface of the eleventh via VA11 inside the second via hole VH2. In a cross-sectional view, the eleventh via VA11 may have a U-shaped cross-section. The second barrier layer BRL2 may be formed or composed of a material including titanium nitride (e.g., TiN_{X}, wherein 0<x≤2; e.g., TiN). For example, the second barrier layer BRL2 may be formed or composed of titanium nitride (e.g., TiN_{X}, wherein 0<x≤2; e.g., TiN).

A second power connection electrode PCE2 may be arranged on the second barrier layer BRL2 and the eleventh via VA11. As described in one or more embodiments, the second power connection electrode PCE2 may be formed or composed of titanium nitride (e.g., TiN_{X}, wherein 0<x≤2; e.g., TiN), and, in one or more embodiments, in a cross-sectional view, the eleventh via VA11 may be surrounded by titanium nitride (e.g., TiN_{X}, wherein 0<x≤2; e.g., TiN). For example, the side, upper and the lower surfaces of the eleventh via VA11 may be surrounded by the titanium nitride (e.g., TiN_{X}, wherein 0<x≤2; e.g., TiN).

According to the display device 10 of one or more embodiments, because the second barrier layer BRL2 is formed or composed of only titanium nitride (e.g., TiN_{X}, wherein 0<x≤2; e.g., TiN), a permeation path of the cleaning solution into the fourth sub-power connection electrode SPCE4 may not be formed or arranged in the process of forming or arranging the second via hole VH2. Accordingly, if (e.g., when) the fourth sub-power connection electrode SPCE4 is formed or composed of a material including aluminum (Al), the fourth sub-power connection electrode SPCE4 may be prevented from being damaged by the cleaning solution (or reduce a degree to or occurrence of which the fourth sub-power connection electrode SPCE4 is damaged by the cleaning solution) used during the process of forming or arranging the second via hole VH2 and the eleventh via VA11. For example, the fourth sub-power connection electrode SPCE4 may be prevented from being melted by the cleaning solution (or a degree to or occurrence of which the fourth sub-power connection electrode SPCE4 is melted by the cleaning solution may be reduced). For example, the eleventh via VA11 is arranged inside the second via hole VH2 of the tenth insulating layer INS10. In one or more embodiments, the second barrier layer BRL2, formed or composed of titanium nitride (e.g., TiN_{X}, wherein 0<x≤2; e.g., TiN), may be arranged between the inner wall of the second via hole VH2 and the eleventh via VA11, and even between the eleventh via VA11 and the fourth sub-power connection electrode SPCE4. This barrier layer surrounds the side surface of the eleventh via VA11 inside the second via hole VH2, providing protection. The second power connection electrode PCE2, also formed or composed of titanium nitride, may be arranged on the second barrier layer BRL2 and the eleventh via VA11, ensuring that the eleventh via VA11 is surrounded by titanium nitride. This configuration prevents and/or blocks the formation of a permeation path for the cleaning solution into the fourth sub-power connection electrode SPCE4, protecting it from damage and/or melting during the cleaning process.

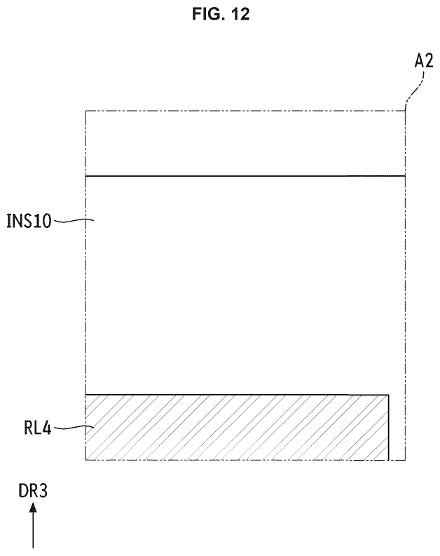

FIGS. 12, 13, 14, 15, 16, and 17 are process cross-sectional views illustrating a method for fabricating a display device according to one or more embodiments.

As illustrated in FIG. 12, a fourth reflective electrode RL4 may be formed or arranged on a substrate (e.g., semiconductor substrate). For example, a first reflective electrode RL1, a second reflective electrode RL2, a third reflective electrode RL3, and the fourth reflective electrode RL4 may be formed or arranged sequentially on a ninth insulating layer INS9 of the semiconductor substrate SSUB. Thereafter, a tenth insulating layer INS10 may be formed or arranged on the fourth reflective electrode RL4 and the ninth insulating layer INS9.

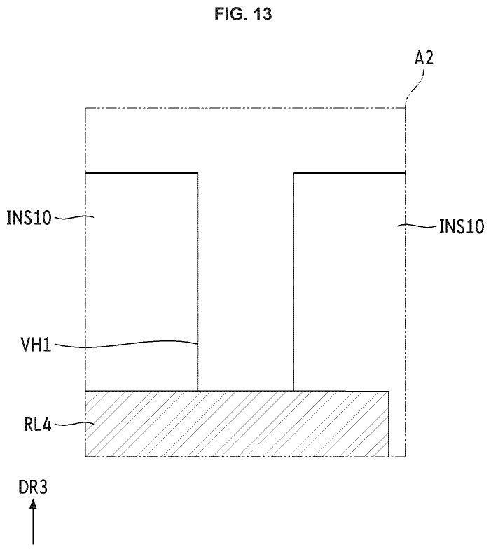

As illustrated in FIG. 13, a first via hole VH1 penetrating the tenth insulating layer INS10 and exposing the fourth reflective electrode RL4 may be formed or arranged. For example, as the tenth insulating layer INS10 is etched by an etching process, a first via hole VH1 may be formed or arranged. In one or more embodiments, a synthetic gas containing a fluorine-based material may be used as an etching gas during the etching process of the tenth insulating layer INS10. At this time, due to the fluorine component of the etching gas, by-products, such as fluorine polymer (e.g., fluorine atom-containing polymer), may be generated during the etching process as described in one or more embodiments. This fluorine polymer may be formed or arranged on the inner wall of the first via hole VH1 and the fourth reflective electrode RL4 (e.g., the fourth reflective electrode RL4 including aluminum) exposed during the etching process.

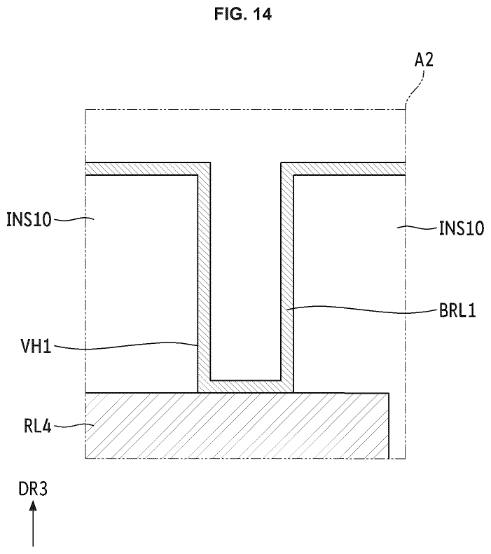

Thereafter, as illustrated in FIG. 14, a first barrier layer BRL1 may be formed or arranged on the tenth insulating layer INS10 utilizing a titanium nitride (e.g., TiN_{X}, wherein 0<x≤2; e.g., TiN) material. At this time, the first barrier layer BRL1 may be connected to the fourth reflective electrode RL4 through a first via hole VH1. For example, the first barrier layer BRL1 may be formed or arranged on the tenth insulating layer INS10, the inner wall of the first via hole VH1, and the fourth reflective electrode RL4. At this time, because the first barrier layer BRL1 is formed or composed of titanium nitride (e.g., TiN_{X}, wherein 0<x≤2; e.g., TiN), the first barrier layer BRL1 and the fluorine polymer as described in one or more embodiments may not react. Accordingly, even if (e.g., when) the first barrier layer BRL1 made of titanium nitride (e.g., TiN_{X}, wherein 0<x≤2; e.g., TiN) is formed or arranged on the fluorine polymer, titanium fluoride (TiF) may not be generated. For example, a permeation path for the cleaning solution used during the cleaning process to be described in more detail herein may not be formed.

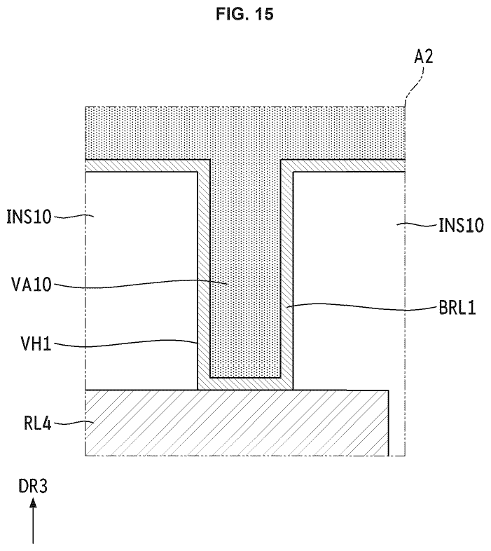

Next, as illustrated in FIG. 15, a tenth via VA10 may be formed or arranged on the first barrier layer BRL1. For example, the tenth via VA10 may be arranged on the first barrier layer BRL1 and overlap the tenth insulating layer INS10. In one or more embodiments, the tenth via VA10 may be arranged inside the first via hole VH1 of the tenth insulating layer INS10. At this time, the side surface of the tenth via VA10 may be surrounded by the first barrier layer BRL1 inside the first via hole VH1. The tenth via VA10 may be, for example, formed or composed of a material including tungsten (W).

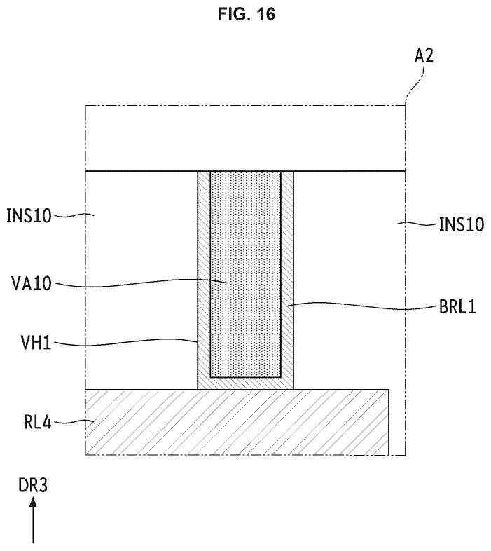

Thereafter, as illustrated in FIG. 16, the first barrier layer BRL1 and the tenth via VA10 formed or arranged on the outer side of the first via hole VH1 may be removed. For example, the first barrier layer BRL1 and the tenth via VA10 on the tenth insulating layer INS10 may be removed through a chemical mechanical polishing (CMP). Accordingly, the first barrier layer BRL1 and the tenth via VA10 may be arranged only in the first via hole VH1. In one or more embodiments, a cleaning process may be performed after the chemical mechanical polishing (CMP). The cleaning solution used during the cleaning process may include hydrogen fluoride (HF). At this time, as described in one or more embodiments, titanium fluoride (TiF) may not be generated because the first barrier layer BRL1 is made of titanium nitride (e.g., TiN_{X}, wherein 0<x≤2; e.g., TiN), and therefore, a permeation path of the cleaning solution into the fourth reflective electrode RL4 may not be formed or arranged. Accordingly, an issue in which the fourth reflective electrode RL4 being damaged by the cleaning solution during the cleaning process may be solved.

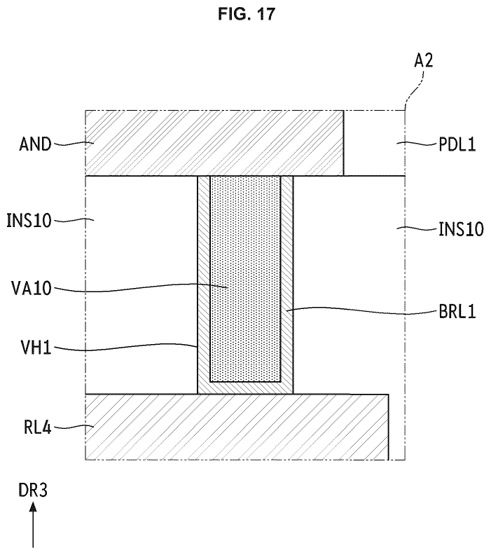

Next, as illustrated in FIG. 17, a first electrode AND may be formed or arranged on the tenth via VA10 and the tenth insulating layer INS10 to contact the tenth via VA10 exposed through the first via hole VH1. The first electrode AND may be formed or composed of, for example, titanium nitride (e.g., TiN_{X}, wherein 0<x≤2; e.g., TiN).

Thereafter, a pixel defining film PDL may be formed or arranged on the first electrode AND, then a light emitting stack IL may be formed or arranged on the first electrode AND and the pixel defining film PDL, and subsequently, a second electrode CAT may be formed or arranged on the light emitting stack IL and the pixel defining film PDL.

In one or more embodiments, a fourth sub-power connection electrode layer SPCE4 of FIG. 11 may be formed or arranged through substantially the same process as the fourth reflective electrode RL4 as described in one or more embodiments, a second via hole VH2 of FIG. 11 may be formed or arranged through substantially the same process as the first via hole VH1 as described in one or more embodiments, an eleventh via VA11 of FIG. 11 may be formed or arranged through substantially the same process as the tenth via VA10 as described in one or more embodiments, a second barrier layer BRL2 of FIG. 11 may be formed or arranged through substantially the same process as the first barrier layer BRL1 as described in one or more embodiments, and a second power connection electrode PCE2 of FIG. 11 may be formed or arranged through substantially the same process as the first electrode AND as described in one or more embodiments. Therefore, the manufacturing process for the fourth sub-power connection electrode SPCE4, the second via hole VH2, the eleventh via VA11, the second barrier layer BRL2, and the second power connection electrode PCE2 of FIG. 11 may refer to the process drawings and related descriptions of FIGS. 12 to 17 as described in one or more embodiments.

The display device 10 according to one or more embodiments may be applied to one or more suitable electronic devices. An electronic device according to one or more embodiments may include the display device 10 as described in one or more embodiments, and may further include, in addition to the display device 10, a module or device having other additional functions.

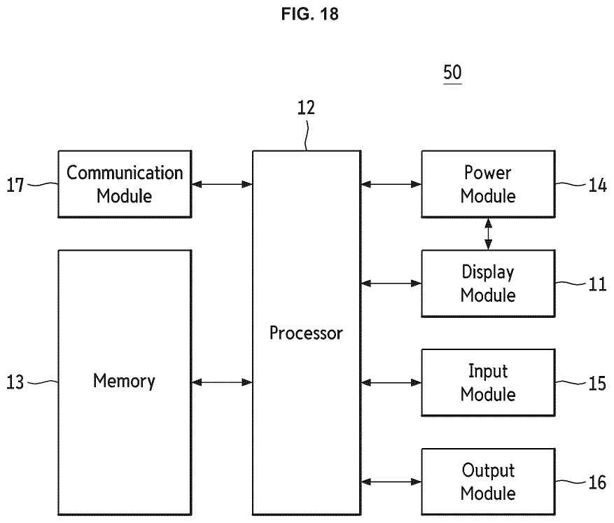

FIG. 18 is a block diagram of an electronic device according to one or more embodiments. Referring to FIG. 18, an electronic device 50 according to one or more embodiments may include a display module 11, a processor 12, a memory 13, and a power module 14. The electronic device 50 may further include an input module 15, a non-visual output module 16, and/or a communication module 17.

The electronic device 50 may be to output one or more suitable information in the form of images through the display module 11. If (e.g., when) the processor 12 executes an application stored in memory 13, image information provided by the application may be provided to a user through the display module 11. The power module 14 may include a power supply module, such as a power adapter and/or a battery device, and a power conversion module that is to convert the power supplied by the power supply module to generate the power desired or required for the operation of the electronic device 50. The input module 15 may be to provide input information to the processor 12 and/or the display module 11. The non-visual output module 16 may act or serve to receive information other than images, such as sound, haptac, luminescence, and/or the like, sent from the processor 12, and provide it to the user. The communication module 17 may be a module responsible for the transmission and reception of information between the electronic device 50 and an external device and may include a receiver and a transmitter.

At least one selected from among each of the components of the electronic device 50 as described in one or more embodiments may be included in the display device according to one or more embodiments. In one or more embodiments, one or more of the individual modules that are functionally included in a single module may be included in the display device, whereas one or more of others thereof may be provided separately from the display device. For example, the display device may include the display module 11, whereas the processor 12, the memory 13, and the power module 14 may be provided in the form of other devices in the electronic device 50, other than the display device.

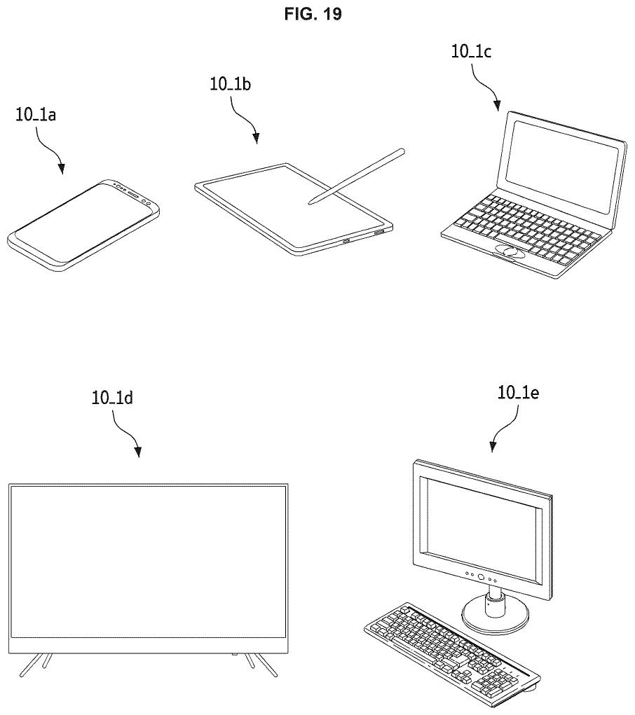

FIGS. 19, 20, and 21 are schematic diagrams illustrating electronic devices according to one or more embodiments. FIGS. 19 to 21 illustrate examples of one or more suitable electronic devices to which the display device 10 according to one or more embodiments are applied.

FIG. 19 illustrates a smartphone 10_1a, a tablet PC 10_1b, a laptop 10_1c, a TV 10_1d, and a desk monitor 10_1e as examples of electronic devices.

The smartphone 10_1a may include a communication module and an input module, such as a touch sensor and/or the like, in addition to the display module 11. The smartphone 10_1a may be to process the information received through the communication module or input module and display the processed information through the display module of the display device.

Each of the tablet PC 10_1b, the laptop 10_1c, the TV 10_1d, and the desk monitor 10_1e may include a display and an input module, similarly to the smartphone 10_1a, and may further include a communication module in one or more cases.

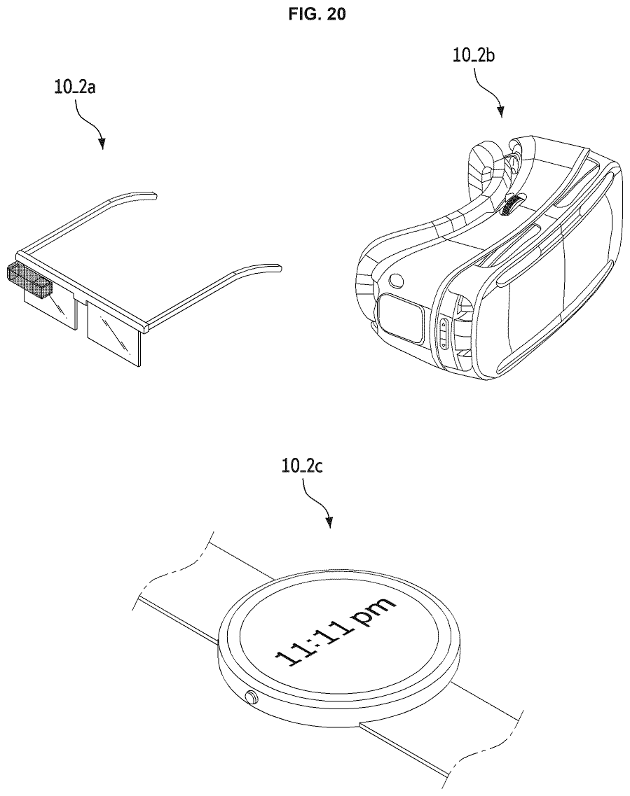

FIG. 20 illustrates a case in which an electronic device including a display module is applied to a wearable electronic device. The wearable electronic device may be smart glasses 10_2a, a head mounted display 10_2b, a smart watch 10_2c, and/or the like.

The smart glasses 10_2a and the head mounted display 10_2b may include a display module that is to output a display image and a reflector that is to reflect the outputted display image to provide it to the user's eyes, thereby providing the user with a virtual reality screen or an augmented reality screen.

The smart watch 10_2c may include a biometric sensor as an input device and may be to provide biometric information recognized through the biometric sensor to the user through a display module.

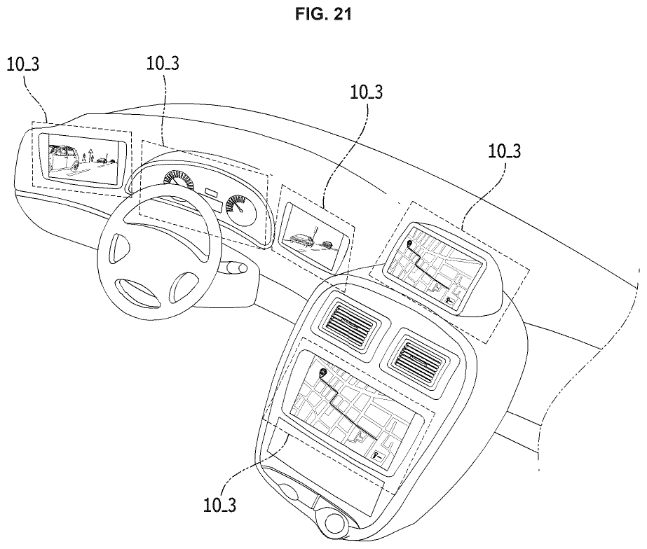

FIG. 21 illustrates a case in which an electronic device including a display module is applied to a vehicle. For example, an electronic device 10_3 may be applied to a dashboard or center fascia of a vehicle or to a center information display (CID) placed in the dashboard of the vehicle or a room mirror display that replaces a side mirror.

A display device, an electronic device, an electronic apparatus, a device for manufacturing substantially the same and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device utilizing a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

While certain embodiments of the present disclosure have been described and illustrated herein, a person having ordinary skill in the art to which the present disclosure pertains shall appreciate that there may be one or more suitable modifications and permutations of the present disclosure without departing from the spirit and scope of the present disclosure that are defined in the appended claims and equivalents thereof. Moreover, it shall be appreciated that the disclosed embodiments are not intended to restrict the aspects and features of the present disclosure thereto and that the technical ideas and aspects of the present disclosure are interpreted to be included within the scope of the appended claims and their equivalents.

What is claimed is:

1. A display device comprising:
a substrate;
a first electrode on the substrate;
a pixel defining film on the first electrode;
a light emitting stack on the first electrode and the pixel defining film;
a second electrode on the light emitting stack;
a reflective electrode between the substrate and the first electrode;
an insulating layer between the reflective electrode and the first electrode;
a first via hole penetrating the insulating layer between the reflective electrode and the first electrode;
a first via inside the first via hole; and
a first barrier layer between the first via hole and the first via,
wherein the first barrier layer is composed of titanium nitride.

2. The display device as claimed in claim 1,
wherein the first barrier layer is further between the reflective electrode and the first via.

3. The display device as claimed in claim 1,
wherein the reflective electrode comprises aluminum.

4. The display device as claimed in claim 1,
wherein the first electrode is composed of substantially the same material as the first barrier layer.

5. The display device as claimed in claim 1,
wherein the first via is composed of a material comprising tungsten.

6. The display device as claimed in claim 1, further comprising:
a power connection electrode connected to the second electrode;
a sub-power connection electrode layer between the substrate and the power connection electrode;
a second via hole penetrating the insulating layer between the power connection electrode and the sub-power connection electrode layer;
a second via inside the second via hole; and
a second barrier layer between the second via hole and the second via,
wherein the insulating layer is further between the sub-power connection electrode layer and the power connection electrode, and
the second barrier layer is composed of titanium nitride.

7. The display device as claimed in claim 6,
wherein the second barrier layer is further between the sub-power connection electrode layer and the second via.

8. The display device as claimed in claim 6,
wherein the sub-power connection electrode layer comprises aluminum.

9. The display device as claimed in claim 6,
wherein the sub-power connection electrode layer is composed of substantially the same material as the second barrier layer.

10. The display device as claimed in claim 6,
wherein the second via is composed of a material comprising tungsten.

11. An electronic device comprising
a display device providing a display screen,
wherein the display device comprises:
a substrate;
a first electrode on the substrate;
a pixel defining film on the first electrode;
a light emitting stack on the first electrode and the pixel defining film;
a second electrode on the light emitting stack;
a reflective electrode between the substrate and the first electrode;
an insulating layer between the reflective electrode and the first electrode;
a first via hole penetrating the insulating layer between the reflective electrode and the first electrode;
a first via inside the first via hole; and
a first barrier layer between the first via hole and the first via,
wherein the first barrier layer is composed of titanium nitride.

12. The electronic device as claimed in claim 11,
wherein the first barrier layer is further between the reflective electrode and the first via.

13. The electronic device as claimed in claim 11,
wherein the reflective electrode comprises aluminum.

14. The electronic device as claimed in claim 11,
wherein the first electrode is composed of substantially the same material as the first barrier layer.

15. The electronic device as claimed in claim 11, further comprising:
a power connection electrode connected to the second electrode;
a sub-power connection electrode layer between the substrate and the power connection electrode;
a second via hole penetrating the insulating layer between the power connection electrode and the sub-power connection electrode layer;
a second via inside the second via hole; and
a second barrier layer between the second via hole and the second via,
wherein the insulating layer is further between the sub-power connection electrode layer and the power connection electrode, and
the second barrier layer is composed of titanium nitride.

16. The electronic device as claimed in claim 15,
wherein the second barrier layer is further between the sub-power connection electrode layer and the second via.

17. The electronic device as claimed in claim 15,
wherein the sub-power connection electrode layer comprises aluminum.

18. The electronic device as claimed in claim 15,
wherein the sub-power connection electrode layer is composed of substantially the same material as the second barrier layer.

19. The electronic device as claimed in claim 11,
wherein the electronic device comprises at least one selected from among VR devices, mobile phones, video phones, smart pads, smart watches, tablet PCs, vehicle displays, monitors, laptops, head mounted displays, and automobiles.

20. A method comprising:
forming a reflective electrode on a substrate;
forming an insulating layer on the reflective electrode;
forming a via hole by penetrating the insulating layer to expose the reflective electrode;
forming a barrier layer formed of titanium nitride on the insulating layer, the insulating layer comprising the via hole;
forming a via on the barrier layer;
removing the via and the barrier layer on the insulating layer;
forming a first electrode on the via;
forming a pixel defining film on the first electrode;
forming a light emitting stack on the first electrode and the pixel defining film; and
forming a second electrode on the light emitting stack and the pixel defining film,
wherein the method is a method for fabricating a display device.
